(19) United States
(12) Patent Application Publication
(10) Pub. No.: US 2024/0415025 A1
(43) Pub. Date: Dec. 12, 2024

(54) STORAGE ELEMENT AND STORAGE DEVICE

(71) Applicant: SONY SEMICONDUCTOR SOLUTIONS CORPORATION, KANAGAWA (JP)

(72) Inventors: YUITO KAGEYAMA, KANAGAWA (JP); YO SATO, KANAGAWA (JP); EIJI KARIYADA, KANAGAWA (JP); MASAKI ENDO, KANAGAWA (JP); MASANORI HOSOMI, KANAGAWA (JP)

(21) Appl. No.: 18/699,351

(22) PCT Filed: Oct. 6, 2022
(86) PCT No.: PCT/JP2022/037358

§ 371 Date: Apr. 8, 2024

(30) Foreign Application Priority Data
Oct. 15, 2021 (JP) 2021-169509

(51) Int. Cl. H10N 50/10; H01F 10/32; H10B 61/00; H10N 50/85

(52) U.S. Cl. CPC H10N 50/10; H10B 61/22; H10N 50/85; H01F 10/329

(57) ABSTRACT

A storage element according to an embodiment includes: a fixed layer that has a fixed magnetization direction; an insulation layer that is disposed on the fixed layer; a storage layer that is disposed on the insulation layer and changes a magnetization direction according to an applied current; and a cap layer that is disposed on the storage layer and made of an oxide, and the cap layer includes a plurality of conductive regions having higher conductivity than conductivity of the oxide.

### FIELD

The present disclosure relates to a storage element and a storage device.

### BACKGROUND

In recent years, as a non-volatile memory used in place of a volatile memory such as a Dynamic Random Access Memory (DRAM) or in combination with a volatile memory, a Magnetic Random Access Memory (MRAM) that stores information in a magnetization direction of a magnetic body has attracted attention.

### CITATION LIST

### Patent Literature

Patent Literature 1: JP 2015-2281 A

### SUMMARY

### Technical Problem

To improve the data retention property of the storage element in the MRAM and reduce a write current, it is effective to increase the magnetic anisotropy of a cap layer and reduce a damping constant. Therefore, conventionally, an oxide such as MgO (magnesium oxide) is generally used for the material of the cap layer.

However, although it is necessary to increase the film thickness of the cap layer to keep the perpendicular magnetic anisotropy of the cap layer even after a wafer process at a high temperature for a long time, there is a problem that increasing the film thickness of the cap layer increases a Resistance Area (RA), decreases a Magnetic Resistance (MR), and increases a write voltage, that is, lowers a device property of the storage element due to superposition of series resistance.

Therefore, the present disclosure proposes a storage element and a storage device whose device property is prevented from lowering.

### Solution to Problem

A storage element according to one embodiment of the present disclosure includes: a fixed layer that has a fixed magnetization direction; an insulation layer that is disposed on the fixed layer; a storage layer that is disposed on the insulation layer and changes a magnetization direction according to an applied current; and a cap layer that is disposed on the storage layer and made of an oxide, wherein the cap layer includes a plurality of conductive regions having higher conductivity than conductivity of the oxide.

### BRIEF DESCRIPTION OF DRAWINGS

FIG. 1 is a schematic diagram illustrating an example of a laminated structure of a magnetic memory element.

FIG. 2 is a graph illustrating a change in a resistance area RA with respect to a film formation time of a cap layer.

FIG. 3 is a graph illustrating a change in a tunnel magnetoresistance TMR with respect to the film formation time of the cap layer.

FIG. 4 is a graph illustrating a change in an anisotropic magnetic field Hk with respect to the film formation time of the cap layer.

FIG. 5 is a graph illustrating a change in a magnetic susceptibility M of a storage layer with respect to an applied magnetic field H in a case where the film formation time of the cap layer was 120 seconds, and heat processing at 400° C. was performed for three hours.

FIG. 6 is a graph illustrating a change in the magnetic susceptibility M of the storage layer with respect to the applied magnetic field H in a case where the film formation time of the cap layer was 160 seconds, and the heat processing at 400° C. was performed for three hours.

FIG. 7 is a graph illustrating a change in the magnetic susceptibility M of the storage layer with respect to the applied magnetic field H in a case where the film formation time of the cap layer was 190 seconds, and the heat processing at 400° C. was performed for three hours.

FIG. 8 is a view illustrating an example of a schematic configuration of a storage device according to a first embodiment.

FIG. 9 is a view illustrating an example of a schematic configuration of a memory cell array according to the first embodiment.

FIG. 10 is a cross-sectional view schematically illustrating an example of a schematic configuration of a magnetic memory element according to the first embodiment.

FIG. 11 is a cross-sectional view illustrating a structure example of a cap layer according to a first example of the first embodiment.

FIG. 12 is a cross-sectional view illustrating a structure example of the cap layer according to a second example of the first embodiment.

FIG. 13 is a cross-sectional view illustrating a structure example of the cap layer according to a third example of the first embodiment.

FIG. 14 is a cross-sectional view illustrating a structure example of the cap layer according to a fourth example of the first embodiment.

FIG. 15 is a cross-sectional view illustrating a structure example of the cap layer according to a fifth example of the first embodiment.

FIG. 16 is a cross-sectional view illustrating a structure example of the cap layer according to a sixth example of the first embodiment.

FIG. 17 is a cross-sectional view illustrating a structure example of the cap layer according to a seventh example of the first embodiment.

FIG. 18 is a cross-sectional view illustrating a structure example of the cap layer according to an eighth example of the first embodiment.

FIG. 19 is a schematic diagram illustrating a layer structure of the magnetic memory element used to inspect the cap layer according to the first embodiment.

FIG. 20 is a graph illustrating a change in the resistance area RA with respect to a film formation time of a MgO film in the layer structure illustrated in FIG. 19.

FIG. 21 is a graph illustrating a change in the tunnel magnetoresistance TMR with respect to the film formation time of the MgO film in the layer structure illustrated in FIG. 19.

FIG. 22 is a graph illustrating a change in the anisotropic magnetic field Hk with respect to the film formation time of the MgO film in the layer structure illustrated in FIG. 19.

FIG. 23 is a graph illustrating a change in the damping constant α with respect to the film formation time of the MgO film in the layer structure illustrated in FIG. 19.

FIG. 24 is a view illustrating a result obtained by actually making the layer structure illustrated in FIG. 19 and observing the layer structure by Scanning Transmission Electron Microscopy (STEM).

FIG. 25 is a cross-sectional view illustrating a structure example of a cap layer according to a first example of a second embodiment.

FIG. 26 is a cross-sectional view illustrating a structure example of the cap layer according to a second example of the second embodiment.

FIG. 27 is a cross-sectional view illustrating a structure example of the cap layer according to a third example of the second embodiment.

FIG. 28 is a cross-sectional view illustrating a structure example of the cap layer according to a fourth example of the second embodiment.

FIG. 29 is a cross-sectional view illustrating a structure example of the cap layer according to a fifth example of the second embodiment.

FIG. 30 is a cross-sectional view illustrating a structure example of the cap layer according to a sixth example of the second embodiment.

FIG. 31 is a cross-sectional view illustrating a structure example of the cap layer according to a seventh example of the second embodiment.

FIG. 32 is a cross-sectional view illustrating a structure example of the cap layer according to an eighth example of the second embodiment.

FIG. 33 is a cross-sectional view illustrating a structure example of a cap layer according to a first example of a third embodiment.

FIG. 34 is a cross-sectional view illustrating a structure example of the cap layer according to a second example of the third embodiment.

FIG. 35 is a cross-sectional view illustrating a structure example of the cap layer according to a third example of the third embodiment.

FIG. 36 is a cross-sectional view illustrating a structure example of the cap layer according to a fourth example of the third embodiment.

FIG. 37 is a cross-sectional view illustrating a structure example of the cap layer according to a fifth example of the third embodiment.

FIG. 38 is a cross-sectional view illustrating a structure example of the cap layer according to a sixth example of the third embodiment.

FIG. 39 is a cross-sectional view illustrating a structure example of the cap layer according to a seventh example of the third embodiment.

FIG. 40 is a cross-sectional view illustrating a structure example of the cap layer according to an eighth example of the third embodiment.

FIG. 41 is a cross-sectional view illustrating a structure example of a cap layer according to a first example of a fourth embodiment.

FIG. 42 is a cross-sectional view illustrating a structure example of the cap layer according to a second example of the fourth embodiment.

FIG. 43 is a cross-sectional view illustrating a structure example of the cap layer according to a third example of the fourth embodiment.

FIG. 44 is a cross-sectional view illustrating a structure example of the cap layer according to a fourth example of the fourth embodiment.

FIG. 45 is a cross-sectional view illustrating a structure example of the cap layer according to a fifth example of the fourth embodiment.

FIG. 46 is a cross-sectional view illustrating a structure example of the cap layer according to a sixth example of the fourth embodiment.

FIG. 47 is a cross-sectional view illustrating a structure example of the cap layer according to a seventh example of the fourth embodiment.

FIG. 48 is a cross-sectional view illustrating a structure example of the cap layer according to an eighth example of the fourth embodiment.

FIG. 49 is a cross-sectional view illustrating a structure example of the cap layer according to a ninth example of the fourth embodiment.

FIG. 50 is a cross-sectional view schematically illustrating an example of a schematic configuration of a magnetic memory element according to a fifth embodiment.

FIG. 51 is a cross-sectional view illustrating a structure example of a cap layer according to a first example of the fifth embodiment.

FIG. 52 is a cross-sectional view illustrating a structure example of the cap layer according to a second example of the fifth embodiment.

FIG. 53 is a cross-sectional view illustrating a structure example of the cap layer according to a third example of the fifth embodiment.

FIG. 54 is a cross-sectional view illustrating a structure example of the cap layer according to a fourth example of the fifth embodiment.

FIG. 55 is a cross-sectional view illustrating a structure example of the cap layer according to a fifth example of the fifth embodiment.

FIG. 56 is a cross-sectional view illustrating a structure example of the cap layer according to a sixth example of the fifth embodiment.

FIG. 57 is a cross-sectional view illustrating a structure example of the cap layer according to a seventh example of the fifth embodiment.

FIG. 58 is a cross-sectional view illustrating a structure example of the cap layer according to an eighth example of the fifth embodiment.

FIG. 59 is a cross-sectional view illustrating a structure example of the cap layer according to a ninth example of the fifth embodiment.

FIG. 60 is a cross-sectional view illustrating a structure example of the cap layer according to a tenth example of the fifth embodiment.

FIG. 61 is a cross-sectional view illustrating a structure example of the cap layer according to an eleventh example of the fifth embodiment.

FIG. 62 is a cross-sectional view illustrating a structure example of the cap layer according to a twelfth example of the fifth embodiment.

FIG. 63 is a cross-sectional view illustrating a structure example of the cap layer according to a thirteenth example of the fifth embodiment.

FIG. 64 is a cross-sectional view illustrating a structure example of the cap layer according to a fourteenth example of the fifth embodiment.

FIG. 65 is a cross-sectional view illustrating a structure example of the cap layer according to a fifteenth example of the fifth embodiment.

FIG. 66 is a cross-sectional view illustrating a structure example of the cap layer according to a sixteenth example of the fifth embodiment.

FIG. 67 is a cross-sectional view illustrating a structure example of the cap layer according to a seventeenth example of the fifth embodiment.

FIG. 68 is a cross-sectional view illustrating a structure example of the cap layer according to an eighteenth example of the fifth embodiment.

FIG. 69 is a cross-sectional view illustrating a structure example of the cap layer according to a nineteenth example of the fifth embodiment.

FIG. 70 is a cross-sectional view illustrating a structure example of the cap layer according to a twentieth example of the fifth embodiment.

FIG. 71 is a cross-sectional view illustrating a structure example of the cap layer according to a twenty first example of the fifth embodiment.

FIG. 72 is a cross-sectional view illustrating a structure example of the cap layer according to a twenty second example of the fifth embodiment.

FIG. 73 is a cross-sectional view illustrating a structure example of the cap layer according to a twenty third example of the fifth embodiment.

FIG. 74 is a cross-sectional view illustrating a structure example of the cap layer according to a twenty fourth example of the fifth embodiment.

FIG. 75 is a cross-sectional view illustrating a structure example of the cap layer according to a twenty fifth example of the fifth embodiment.

FIG. 76 is a cross-sectional view illustrating a structure example of the cap layer according to a twenty sixth example of the fifth embodiment.

FIG. 77 is a cross-sectional view illustrating a structure example of the cap layer according to a twenty seventh example of the fifth embodiment.

FIG. 78 is a cross-sectional view illustrating a structure example of the cap layer according to a twenty eighth example of the fifth embodiment.

FIG. 79 is a cross-sectional view illustrating a structure example of the cap layer according to a twenty ninth example of the fifth embodiment.

FIG. 80 is a cross-sectional view illustrating a structure example of the cap layer according to a thirtieth example of the fifth embodiment.

FIG. 81 is a cross-sectional view illustrating a structure example of the cap layer according to a thirty first example of the fifth embodiment.

FIG. 82 is a cross-sectional view illustrating a structure example of the cap layer according to a thirty second example of the fifth embodiment.

FIG. 83 is a cross-sectional view illustrating a structure example of the cap layer according to a thirty third example of the fifth embodiment.

### DESCRIPTION OF EMBODIMENTS

Hereinafter, embodiments of the present disclosure will be described in detail with reference to the drawings. Note that, in the following embodiments, the same parts will be assigned the same reference numerals, and redundant description will be omitted.

Furthermore, the present disclosure will be described in order of items described below.
0. Introduction
1. First Embodiment
   1.1 Schematic Configuration Example of Storage Device
   1.2 Schematic Configuration Example of Memory Cell Array
   1.3 Schematic Configuration Example of Magnetic Memory Element
   1.4 Schematic Configuration Example of Cap Layer
   1.5 Schematic Structure Example of Cap Layer
      1.5.1 First Example
      1.5.2 Second Example
      1.5.3 Third Example
      1.5.4 Fourth Example
      1.5.5 Fifth Example
      1.5.6 Sixth Example
      1.5.7 Seventh Example
      1.5.8 Eighth Example
   1.6 Function/Effect
2. Second Embodiment
3. Third Embodiment
4. Fourth Embodiment
5. Fifth Embodiment
   5.1 Schematic Configuration Example of Magnetic Memory Element
   5.2 Schematic Structure Example of Cap Layer

### 0. Introduction

A magnetoresistive element that is a core technique of an MRAM generally has a laminated structure of a fixed layer/a barrier layer/a storage layer/a cap layer in order from the bottom. An oxide such as MgO is used as the barrier layer and the cap layer, and a magnetization direction is controlled in a direction vertical to a film surface by the magnetic anisotropy at an interface with a ferromagnetic layer. A conventional technique has a problem that it is necessary to increase the film thickness of a MgO film that is the cap layer to maintain the data retention property by keeping the magnetization direction of the storage layer in the vertical direction even after a heat load is applied at a relatively high temperature for a long time in a manufacturing process, and the device property such as the write property and the read property deteriorates due to an increase of a resistance value.

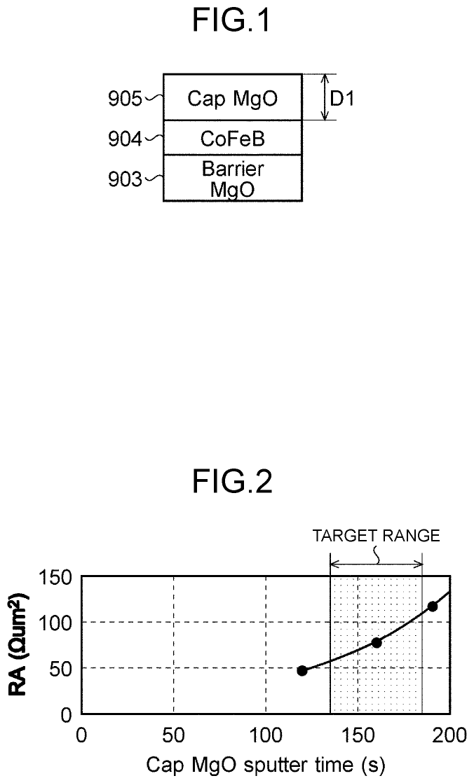

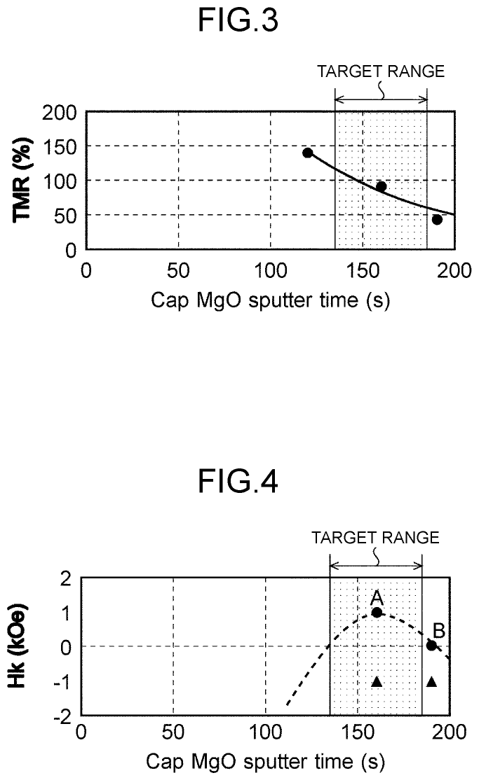

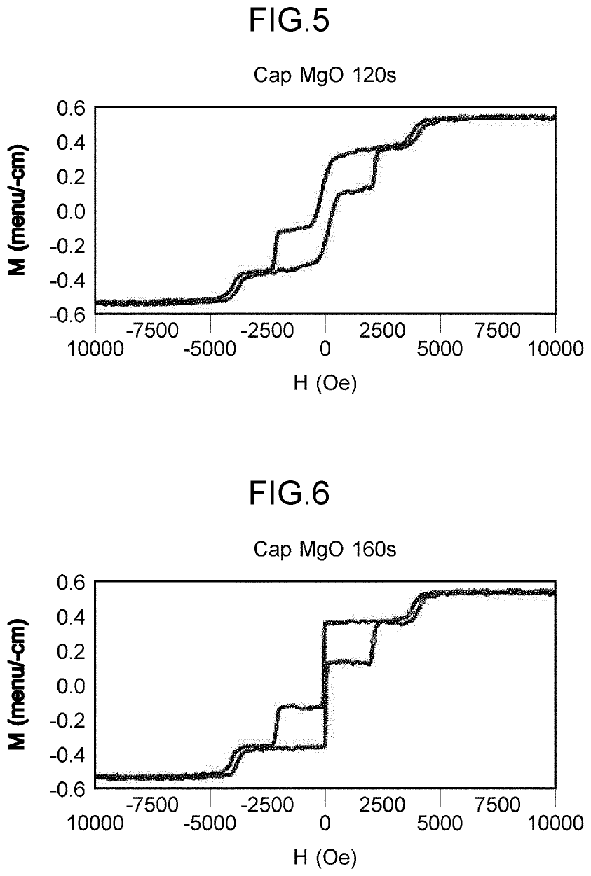

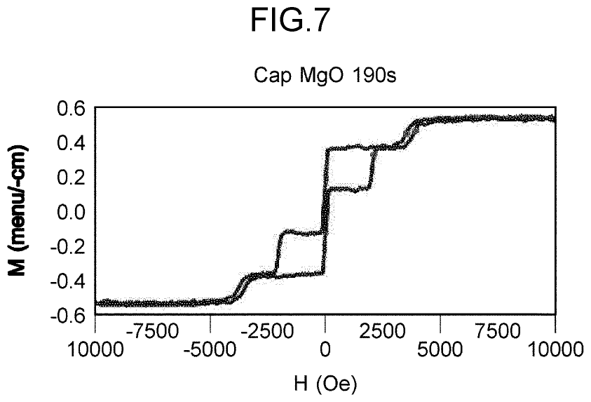

Here, FIGS. 2 to 7 illustrate results obtained by using MgO for each of materials of a barrier layer 903 and a cap layer 905 in a laminated structure illustrated in FIG. 1 and including the barrier layer 903, a storage layer 904, and the cap layer 905, and conducting an experiment assuming a heat load at a relatively high temperature for a long time. Note that FIG. 2 is a graph illustrating a change in a resistance area RA with respect to a film formation time of a cap layer (MgO film) (i.e., a film thickness D of the cap layer, the same applies hereinafter). FIG. 3 is a graph illustrating a change in a tunnel magnetoresistance TMR with respect to the film formation time of the cap layer (MgO film). FIG. 4 is a graph illustrating a change in an anisotropic magnetic field Hk with respect to the film formation time of the cap layer (MgO film). Note that, in FIG. 4, black circles indicate a case where heat processing at 400° C. was performed for three hours, and black triangles indicate a case where heat processing at 400° C. was performed for 10 minutes. Furthermore, FIGS. 5 to 7 illustrate graphs illustrating changes in a magnetic susceptibility M of the storage layer with respect to an applied magnetic field H in a case where film formation times of the cap layer (MgO film) were 120 seconds, 160 seconds, and 190 seconds and the heat processing at 400° C. was performed for three hours. Note that FIG. 6 corresponds to a point A in FIG. 4, and FIG. 7 corresponds to a point B in FIG. 4.

It is found from FIGS. 4 and 5 to 7 that it is necessary to set the film thickness D of the cap layer 905 to approximately one nm (nanometer) (corresponding to approximately 160 seconds of the film formation time) and apply a heat load at a high temperature for a long time to satisfy a condition (anisotropic magnetic field Hk>0) that the magnetization direction of the storage layer 904 can be controlled in the direction vertical to the film surface. However, as illustrated in FIGS. 2 and 3, it has become clear that a problem occurs that, when the cap layer 905 is formed so as to satisfy the condition (anisotropic magnetic field Hk>0) illustrated in FIG. 4, and then the heat load is applied at the relatively high temperature for the long time, the resistance area RA increases to 50 Ωμm² or more (see FIG. 2), and the tunnel magnetoresistance TMR decreases to 100% or less (see FIG. 3).

Hence, the following embodiments embody a storage element that has a low resistance while having a good data retention property by disposing regions having conductivity in a cap layer in a distributed manner, and propose the storage element and a storage device whose device property such as the write property and the read property is prevented by each storage element from lowering.

### 1. First Embodiment

First, a storage element and a storage device according to the first embodiment of the present disclosure will be described in detail with reference to the drawings.

### 1.1 Schematic Configuration Example of Storage Device

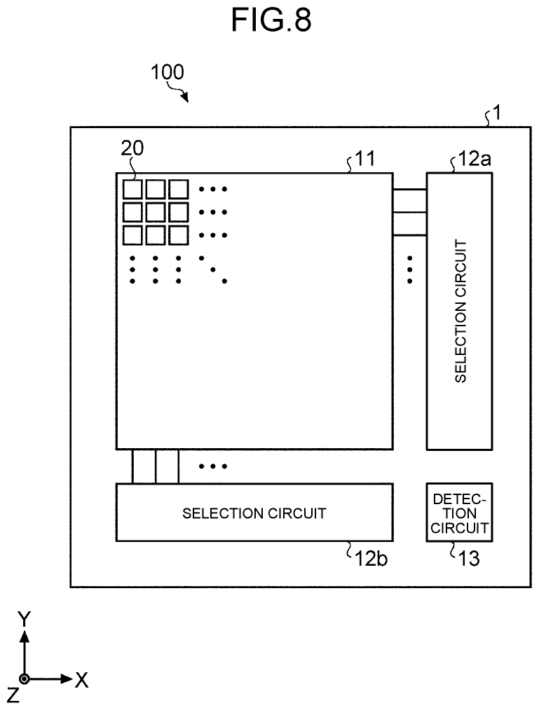

FIG. 8 is a view illustrating an example of a schematic configuration of the storage device according to the present embodiment. As illustrated in FIG. 8, a storage device 100 includes a memory macro 1. The memory macro 1 includes a memory cell array 11, a detection circuit 13, and selection circuits 12a and 12b.

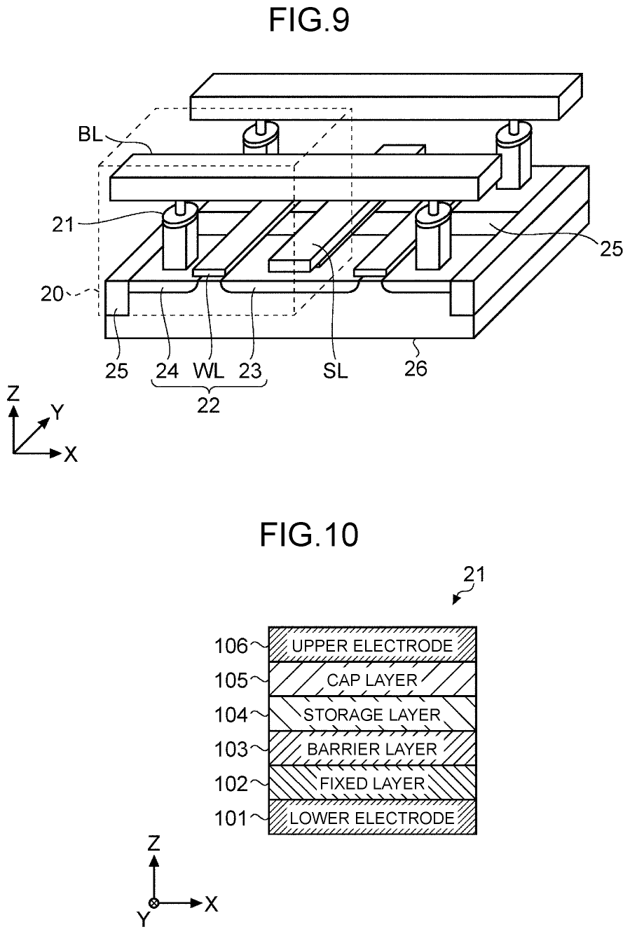

The memory cell array 11 includes a plurality of memory cells 20. The plurality of memory cells 20 are disposed in a matrix pattern in an X axis direction and a Y axis direction. As described later with reference to FIG. 9, the one memory cell 20 includes one magnetic memory element. In this sense, the memory cell array 11 may be also referred to as a memory element array including a plurality of magnetic memory elements.

### 1.2 Schematic Configuration Example of Memory Cell Array

FIG. 9 is a view illustrating an example of a schematic configuration of the memory cell array according to the present embodiment. The memory cell array 11 includes a semiconductor substrate 26 and wirings in addition to magnetic memory elements 21. The wirings are exemplified as bit lines BL, word lines WL, and a sense line SL. The semiconductor substrate 26 may be, for example, a semiconductor substrate such as a silicon substrate.

A plurality of the bit lines BL, a plurality of the word lines WL, and a plurality of the sense lines SL exist, and extend from the memory cell array 11, that is, the plurality of magnetic memory elements 21 to the selection circuits 12a and 12b (FIG. 8). The bit line BL and the word line WL are two types of address wirings that cross each other. The sense line SL is provided in association with the bit line BL. In this example, the bit line BL extends in the X axis direction, and the word line WL extends in the Y axis direction.

The magnetic memory elements 21 are disposed on the semiconductor substrate 26 (on a Z axis positive direction side in this example). Each magnetic memory element 21 is disposed in association with an intersection (e.g., near the intersection) of the bit line BL and the word line WL. One terminal of the magnetic memory element 21 is connected to the bit line BL. For example, an unillustrated upper electrode of the magnetic memory element 21 is electrically connected to the bit line BL. The other terminal of the magnetic memory element 21 is connected to a selection transistor 22. For example, an unillustrated lower electrode of the magnetic memory element 21 is connected to the selection transistor 22.

Note that the word “connected” may mean electrical connection. Another element may be interposed between elements connected to each other as long as the functions of the elements are not lost.

The semiconductor substrate 26 includes a plurality of the selection transistors 22 and an element isolation region 25. The element isolation region 25 provides an electrically isolated region. The selection transistors 22 are formed in a region isolated by the element isolation region 25. Each of the plurality of selection transistors 22 is associated with the one magnetic memory element 21, and is provided to select this magnetic memory element 21.

As indicated by a broken line in FIG. 9, the one memory cell 20 includes the associated magnetic memory element 21 and selection transistor 22. FIG. 9 schematically illustrates portions associated with the four memory cells 20 among the plurality of memory cells 20 included in the memory cell array 11. In the one memory cell 20, the magnetic memory element 21 and the selection transistor 22 are connected between the associated bit line BL and sense line SL.

The exemplified selection transistor 22 is a Field Effect Transistor (FET), and includes a source region 23, a drain region 24, and a channel formation region. A gate electrode provided to the channel formation region is connected to the word line WL. In an example illustrated in FIG. 9, the word line WL includes the gate electrode. The source region 23 is connected with the sense line SL. The drain region 24 is connected to the other terminal of the magnetic memory element 21. Note that, in this example, the source region 23 is formed commonly as the source region 23 of the adjacent selection transistor 22.

The magnetic memory element 21 is connected between the drain region 24 of the selection transistor 22 and the bit line BL in a Z axis direction using, for example, a via wiring or the like.

The bit line BL, the word line WL, and the sense line SL are connected to the selection circuits 12a and 12b (FIG. 8) to make it possible to apply a voltage to the magnetic memory element 21, and cause a desired current to flow. At a time of writing of information, a voltage for causing a current to flow to the magnetic memory element 21 is applied via the bit line BL and the sense line SL associated with a desired memory cell. When the voltage is applied to the word line WL associated with a desired memory cell, that is, the gate electrode of the selection transistor 22, and the selection transistor 22 is turned on (conducted state), the current flows through the magnetic memory element 21. The current flows to the magnetic memory element 10, and information is written (stored) by spin torque magnetization reversal. At a time of reading of information, the voltage is applied to the word line WL associated with a desired memory cell, that is, the gate electrode of the selection transistor 22, and the current flowing between the bit line BL and the sense line SL, that is, the current flowing through the magnetic memory element 21 is detected. Detection of the current means detection of the magnitude of an electric resistance, and information is read by this detection.

### 1.3 Schematic Configuration Example of Magnetic Memory Element

FIG. 10 is a cross-sectional view schematically illustrating an example of a schematic configuration of a magnetic memory element according to the present embodiment. The magnetic memory element 21 is, for example, a perpendicular magnetization type Spin-Transfer-Torque (STT)-MRAM, and has a laminated structure. The Z axis direction corresponds to a lamination direction (vertical direction). The X axis direction and the Y axis direction correspond to an extension direction (plane direction) of the layers.

The magnetic memory element 21 includes a lower electrode 101, a fixed layer 102, a barrier layer 103, a storage layer 104, a cap layer 105, and an upper electrode 106. In this example, the lower electrode 101, the fixed layer 102, the barrier layer 103, the storage layer 104, the cap layer 105, and the upper electrode 106 are laminated in this order toward the Z axis positive direction. Note that an upper tunnel barrier layer and/or an upper magnetization fixed layer may be disposed between the storage layer 104 and the cap layer 105.

Although the magnetization orientation of the storage layer 104 is reversed by spin torque magnetization reversal, magnetization arrangement of the fixed layer 102 is not reversed, and the storage layer 104 and the fixed layer 102 are in an antiparallel state. In such a spin injection memory, “0” and “1” of information are defined by the magnetization direction (upward or downward) of the storage layer 104.

The fixed layer 102 and the storage layer 104 are layers made of, for example, a ferromagnetic body containing at least one type of 3d transition metals. The barrier layer 103 that is a tunnel barrier layer (tunnel insulation layer) is provided between the storage layer 104 and the fixed layer 102 to form an MTJ element. By adjusting the film thickness of the storage layer 104 to three nm or less, it is possible to control the magnetization direction in the direction vertical to the film surface by the magnetic anisotropy at the interface with the barrier layer 103. The lower electrode 101 is disposed under the fixed layer 102, and the cap layer 105 is disposed on the storage layer 104. Details of the cap layer 105 will be described later.

The lower electrode 101 and the upper electrode 106 are conductive layers made of, for example, a metal such as Au, Cu, Al, Ti, Mo, Ru, Ta, Pt, Ir, or W, or an alloy thereof. However, the metal is not limited thereto, and various conductive materials may be used.

The barrier layer 103 is, for example, an insulation layer containing oxygen atoms. As a material of the barrier layer 103, for example, MgO (magnesium oxide) can be used. However, the material of the barrier layer 103 is not limited thereto, and the barrier layer 103 may be formed by, for example, using various insulators, dielectrics, and semiconductors such as Al₂O₃ (aluminum oxide), CaO (calcium oxide), SrO (strontium oxide), TiO (titanium oxide), EuO (europium oxide), ZrO (zirconium oxide), AlN (aluminum nitride), SiO₂, Bi₂O₃, MgF₂, CaF, SrTiO₂, AlLaO₃, and Al—N—O may be used.

The storage layer 104 is made of a ferromagnetic body having a magnetic moment whose magnetization direction freely changes in a layer surface vertical direction (Z axis direction). The fixed layer 102 is made of a ferromagnetic body having a magnetic moment whose magnetization is fixed in the layer surface vertical direction.

Information is stored according to the magnetization orientation of the storage layer having the uniaxial (e.g., Z axis direction) anisotropy. Writing is performed by applying a current in the layer surface vertical direction, and causing spin torque magnetization reversal. The fixed layer 102 is provided to the storage layer 104 whose magnetization orientation is reversed by spin injection with the barrier layer 103 interposed therebetween, and is used as a reference for storage information (magnetization direction) of the storage layer 104.

An example of the materials of the storage layer 104 and the fixed layer 102 is Co—Fe—B. Since the fixed layer 102 is the reference of information, it is required that the magnetization direction does not change as a result of recording or reading. However, the magnetization direction does not necessarily need to be fixed in a specific direction, and a magnetic coercive force may be made larger or the layer thickness (or the film thickness) may be made larger than that of the storage layer 104, or a magnetic damping constant may be made larger to make the fixed layer 102 more hardly movable than the storage layer 104. In the case where magnetization is fixed, an antiferromagnetic body such as PtMn or IrMn may be brought into contact with the fixed layer 102, or the magnetic body that is in contact with the antiferromagnetic bodies may be magnetically coupled with a nonmagnetic body such as Ru interposed therebetween to indirectly fix the fixed layer 102.

In the present embodiment, the composition of the storage layer 104 is adjusted such that the magnitude of an effective demagnetization field received by a perpendicular magnetization layer in the storage layer 104 is smaller than a saturation magnetization amount (hereinafter, also referred to as a “saturation magnetization amount Ms”). As described above, a ferromagnetic material Co—Fe—B composition of the storage layer 104 is selected, and the magnitude of the effective demagnetization field received by the storage layer 104 is decreased so as to be smaller than the saturation magnetization amount Ms of the storage layer 104. As a result, magnetization of the storage layer 104 is directed toward the layer surface vertical direction.

Furthermore, in the present embodiment, by making the barrier layer 103 a magnesium oxide layer, it is possible to increase a magnetoresistance change rate (MR rate). By increasing the MR rate in this way, it is possible to improve spin injection efficiency, and reduce the current density required for reversing the magnetization orientation of the storage layer 104. Furthermore, the material of the barrier layer 103 may be replaced with a metal material as an intermediate layer, and spin injection may be performed by a Giant Magneto Resistive (GMR) effect.

According to the above-described magnetic memory element 21, the storage layer 104 of the magnetic memory element 21 is configured such that the magnitude of the effective demagnetization field received by the storage layer 104 is smaller than the saturation magnetization amount (also referred to as the saturation magnetization amount Ms) of the storage layer 104. The demagnetization field received by the storage layer 104 is low, so that it is possible to reduce a write current amount necessary for reversing the magnetization orientation of the storage layer 104. This is because the storage layer 104 has the perpendicular magnetic anisotropy, and consequently is advantageous in terms of the demagnetization field at a time of application of the reversal current of the perpendicular magnetization STT-MRAM.

On the other hand, it is possible to reduce the write current amount without reducing the saturation magnetization amount Ms of the storage layer 104, so that it is possible to secure thermal stability of the storage layer 104 by setting the saturation magnetization amount Ms of the storage layer 104 to a sufficient amount. Furthermore, the fixed layer 102 has a laminated ferri-pin structure, so that it is possible to make the fixed layers blunt with respect to an external magnetic field, block a leakage magnetic field caused by the fixed layers, and enhance the perpendicular magnetic anisotropy of the fixed layer 102 by interlayer coupling of a plurality of magnetic layers. Consequently, it is possible to sufficiently secure the thermal stability that is the information retention capability, and consequently configure the magnetic memory element 21 having an excellent property balance.

As described above, the information is stored (written) according to the magnetization orientation of the storage layer 104 having the uniaxial anisotropy. Writing is performed by applying a current in the layer surface vertical direction (Z axis direction) and causing spin torque magnetization reversal.

### 1.4 Schematic Configuration Example of Cap Layer

Although it is necessary to set a film thickness D of the cap layer 105 to approximately one nm (nanometer) and apply a heat load at a high temperature for a long time as described above to satisfy the condition (anisotropic magnetic field Hk>0) that the magnetization direction of the storage layer 104 can be controlled in the direction vertical to the film surface in the above-described element structure, forming the cap layer 105 and applying a heat load at a relatively high temperature for a long time to satisfy the anisotropic magnetic field Hk>0 causes a problem that failures such as an increase in a resistance area RA and a decrease in the tunnel magnetoresistance TMR occur, and a device property such as a write property and a read property deteriorates.

Therefore, in the present embodiment, as described above, regions having conductivity are disposed in the cap layer in a distributed manner. Consequently, even when the film thickness D of the cap layer 105 is increased and a heat load is applied at a high temperature for a long time so as to satisfy the anisotropic magnetic field Hk>0, it is possible to suppress an increase in a resistance value of the cap layer 105, so that it is possible to embody a storage element having a low resistance while having a good data retention property. As a result, it is possible to embody a storage element and a storage device whose device property such as the write property and the read property is prevented from lowering.

In the present embodiment, the cap layer 105 has the structure that the regions having conductivity (hereinafter, also referred to as conductive regions) are disposed in the oxide layer in a distributed manner. The conductive region is a region made of a material having higher conductivity than that of the oxide constituting the cap layer 105. The conductive regions in the cap layer 105 function as conduction paths of at least one of metal conduction, hopping conduction, tunnel conduction, and thermally active conduction, so that it is possible to reduce a substantial resistance value of the cap layer 105, and consequently it is possible to suppress an increase in the resistance value even when the film thickness of the cap layer 105 is increased.

As the material of the cap layer 105, for example, MOx (M═Si, Mg, Sc, Ti, V, Cr, Ca, Zn, Y, Zr, Mo, Ru, Hf, Ta, W, Re, La, Gd, or Tb) that is an oxide, and a material obtained by adding metal elements (e.g., at least one of Ti, Mo, Al, Co, Fe, V, Cr, Cu, Zn, Nb, Y, Zr, Hf, Au, Pt, Ir, Pd, Ru, Ta, W, Sr, and Ba) to the above oxide may be used. In this case, the conductive regions may be, for example, regions including at least one of, for example, Ti, Mo, Al, Co, Fe, V, Cr, Cu, Zn, Nb, Y, Zr, Hf, Au, Pt, Ir, Pd, Ru, Ta, W, Sr, and Ba. However, the cap layer 105 is not limited thereto, and may be, for example, a laminated film including at least two layers of a layer including at least one of the above oxide and a material obtained by adding third metal elements to the oxide, and a layer including at least one of metals (e.g., Ru, Ta, W, Mo, Ti, Mg, Co, Fe, Al, V, Cr, Cu, Zn, Nb, Y, Zr, Hf, Au, Pt, Ir, and Pd).

Furthermore, the plurality of conductive regions disposed in the cap layer 105 may be structures formed by patterning a conductive film such as a metal film by photolithography or the like, or may be a structure formed by growing metal elements or the like in an island shape by segregation. Alternatively, the plurality of conductive regions may be structures that have granular structures aggregated and segregated by thermal diffusion of the metal elements.

At that time, by using a conductive material having low wettability with respect to a material for forming the surface on which the conductive regions are formed (e.g., a material for forming the storage layer 104 or the cap layer 105), it is possible to efficiently segregate the conductive regions (e.g., metal elements) on a formation surface, so that it is possible to increase manufacturing efficiency.

Note that a coverage of the conductive regions with respect to the surface on which the conductive regions are formed may be 1 to 99%.

A film thickness t of the cap layer 105 may be, for example, 10≤t≤40 [Å (angstroms)]. In that case, by making a minimum thickness t_min of the oxide film obtained by excluding the conductive regions from the cap layer 105 thinner than 10 [angstroms], it is possible to satisfy the condition (anisotropic magnetic field Hk>0) that the magnetization direction of the storage layer 104 can be controlled in the direction vertical to the film surface, and obtain a good device property.

Particularly when the film thickness t of the oxide is approximately 20 angstroms, an average radius r of the plurality of conductive regions is approximately 8 angstroms, and an average distance d between adjacent conductive regions is approximately 30 angstroms, it is possible to expect significant improvement of the device property.

### 1.5 Schematic Structure Example of Cap Layer

Next, structure examples of the cap layer 105 according to the present embodiment will be described below citing some examples.

### 1.5.1 First Example

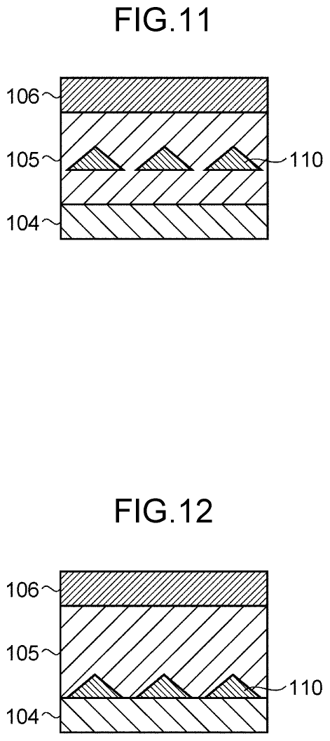

FIG. 11 is a cross-sectional view illustrating the structure example of the cap layer according to the first example. As illustrated in FIG. 11, the cap layer 105 according to the first example has a structure that is provided with a plurality of conductive regions 110. In this example, the plurality of conductive regions 110 may be disposed, for example, in the vicinity of the middle between the upper surface and the bottom surface of the cap layer 105, in other words, in the vicinity of the middle in the layer surface vertical direction (Z axis direction). The plurality of conductive regions 110 may be substantially uniformly distributed in, for example, a plane parallel to an element formation surface. At that time, the plurality of conductive regions 110 may be aligned regularly or irregularly.

Note that, although this example and the following examples exemplify cases where the cross-sectional shape (hereinafter, also referred to as a vertical cross-sectional shape) of the layer surface vertical surface of the individual conductive region 110 is a substantially triangular shape, the cross-sectional shape is not limited thereto. Furthermore, the cross-sectional shape (hereinafter, also referred to as a horizontal cross-sectional shape) of a plane parallel to the element formation surface of the individual conductive region 110 may be a regular shape such as a circular shape, an elliptical shape, or a polygonal shape, or may be a randomly distorted shape. Furthermore, the size of each conductive region 110 may be, for example, 0.1 to approximately several nm.

The conductive regions 110 in the middle of this cap layer 105 can be formed by, for example, forming a film of the cap layer 105 up to the middle thereof using a sputtering method or the like, depositing metal elements by sputtering on the upper surface of the oxide film formed by the film formation (metal atoms are segregated), or forming the plurality of conductive regions 110 by patterning using photolithography, and then forming a film of the oxide film using the sputtering method or the like on the surface on which the plurality of conductive regions 110 are formed. In this regard, the method for forming the cap layer 105 is not limited thereto, and may be variously modified.

As described above, in the case of the structure that the plurality of conductive regions 110 are disposed in the middle of the cap layer 105, the conduction paths from the storage layer 104 of the lower layer to the upper electrode 106 of the upper layer can be classified into the conduction paths from the storage layer 104 to the conductive regions 110 and the conduction paths from the conductive regions 110 to the upper electrode 106, so that it is possible to more effectively reduce the substantial resistance value of the cap layer 105. As a result, it is possible to further increase the film thickness of the cap layer 105.

### 1.5.2 Second Example

FIG. 12 is a cross-sectional view illustrating the structure example of the cap layer according to the second example. As illustrated in FIG. 12, the cap layer 105 according to the second example has a structure that the plurality of conductive regions 110 are provided on the upper surface of the storage layer 104 that is a lower layer. Similar to the first example, the plurality of conductive regions 110 may be regularly or irregularly and substantially uniformly distributed in, for example, a plane parallel to the element formation surface.

The conductive regions 110 in the middle of this cap layer 105 can be formed by, for example, a two-stage film forming process that uses a sputtering method or the like. For example, the plurality of conductive regions 110 can be formed by depositing by sputtering (metal atoms are segregated) or patterning by photolithography the metal elements on the upper surface of the storage layer 104, and an oxide film can be formed as a film on the storage layer 104 on which the plurality of conductive regions 110 are formed by using a sputtering method or the like. In this regard, the method for forming the cap layer 105 is not limited thereto, and may be variously modified.

Consequently, in the case of the structure that the plurality of conductive regions 110 are disposed on the upper surface of the storage layer 104, it is possible to form the cap layer 105 in the two-stage film forming process, so that it is possible to simplify the manufacturing process. Furthermore, in a case where the conductive regions 110 are formed by segregation, a material having low wettability with respect to the storage layer 104 can be used for the conductive regions 110, so that it also becomes easy to select the material.

### 1.5.3 Third Example

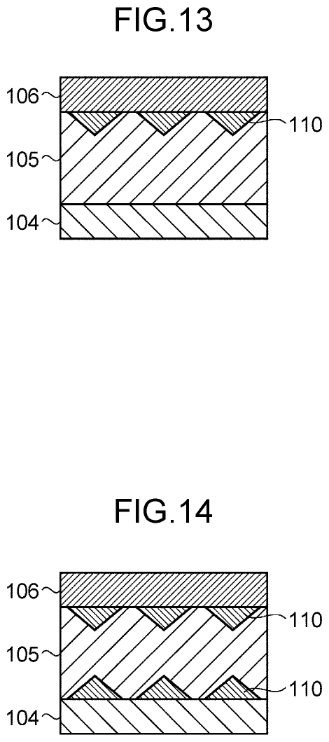

FIG. 13 is a cross-sectional view illustrating the structure example of the cap layer according to the third example. As illustrated in FIG. 13, the cap layer 105 according to the third example has a structure that the plurality of conductive regions 110 are provided at an upper layer portion of the cap layer 105, that is, on the lower surface of the upper electrode 106. Similar to the first example, the plurality of conductive regions 110 may be regularly or irregularly and substantially uniformly distributed in, for example, a plane parallel to the element formation surface.

Similar to the second example, the conductive regions 110 in the middle of the cap layer 105 can be formed by, for example, the two-stage film forming process that uses the sputtering method or the like. By, for example, forming a film of an oxide film on the storage layer 104 using the sputtering method or the like, and depositing by sputtering (metal atoms are segregated) or patterning by photolithography the metal elements on the oxide film formed by the film formation, it is possible to form the conductive regions 110. In this regard, the method for forming the cap layer 105 is not limited thereto, and may be variously modified.

As described above, in the case of the structure that the plurality of conductive regions 110 are disposed on the upper surface of the storage layer 104, the cap layer 105 can be formed in the two-stage film forming process similar to the second example, so that it is possible to simplify the manufacturing process.

### 1.5.4 Fourth Example

FIG. 14 is a cross-sectional view illustrating the structure example of the cap layer according to the fourth example. As illustrated in FIG. 14, the cap layer 105 according to the fourth example has a structure obtained by combining the second example and the third example. That is, in the fourth example, the cap layer 105 has the structure that the plurality of conductive regions 110 are disposed both on the storage layer 104 and under the upper electrode 106.

Consequently, by adopting the structure that the plurality of conductive regions 110 are disposed both on the storage layer 104 and under the upper electrode 106, it is possible to shorten an electrical distance from the storage layer 104 to the upper electrode 106, so that it is possible to more effectively reduce a substantial resistance value of the cap layer 105.

Note that, since the method for manufacturing the cap layer 105 according to this example can be easily arrived at from a combination of the manufacturing methods described in the second example and the third example, description thereof is omitted here.

### 1.5.5 Fifth Example

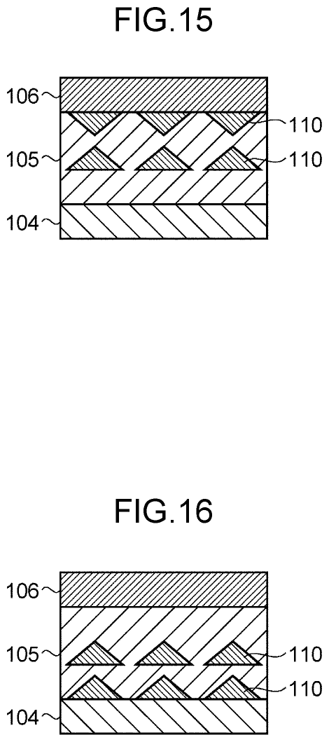

FIG. 15 is a cross-sectional view illustrating the structure example of the cap layer according to the fifth example. As illustrated in FIG. 15, the cap layer 105 according to the fifth example has the structure obtained by combining the first example and the third example. That is, in the fifth example, the cap layer 105 has the structure that the plurality of conductive regions 110 are disposed both in the middle of the cap layer 105 and under the upper electrode 106.

As described above, by adopting the structure that the plurality of conductive regions 110 are disposed both in the middle of the cap layer 105 and under the upper electrode 106, it is possible to shorten an electrical distance from the storage layer 104 to the upper electrode 106 similar to the fourth example, so that it is possible to more effectively reduce a substantial resistance value of the cap layer 105.

Note that, since the method for manufacturing the cap layer 105 according to this example can be easily arrived at from a combination of the manufacturing methods described in the first example and the third example, description thereof is omitted here.

### 1.5.6 Sixth Example

FIG. 16 is a cross-sectional view illustrating the structure example of the cap layer according to the sixth example. As illustrated in FIG. 16, the cap layer 105 according to the sixth example has a structure obtained by combining the first example and the second example. That is, in the sixth example, the cap layer 105 has the structure that the plurality of conductive regions 110 are disposed both in the middle of the cap layer 105 and on the storage layer 104.

As described above, by adopting the structure that the plurality of conductive regions 110 are disposed both in the middle of the cap layer 105 and on the storage layer 104, it is possible to shorten an electrical distance from the storage layer 104 to the upper electrode 106 similar to the fourth example, so that it is possible to more effectively reduce a substantial resistance value of the cap layer 105.

Note that, since the method for manufacturing the cap layer 105 according to this example can be easily arrived at from a combination of the manufacturing methods described in the first example and the second example, description thereof is omitted here.

### 1.5.7 Seventh Example

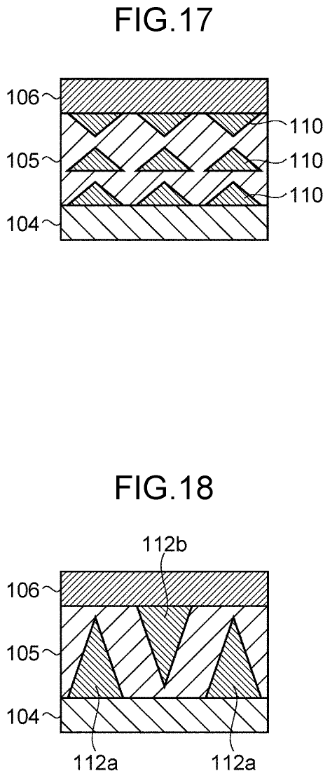

FIG. 17 is a cross-sectional view illustrating the structure example of the cap layer according to the seventh example. As illustrated in FIG. 17, the cap layer 105 according to the seventh example has a structure obtained by combining the first example, the second example, and the third example. That is, in the sixth example, the cap layer 105 has the structure that the plurality of conductive regions 110 are disposed respectively on the storage layer 104, in the middle of the cap layer 105, and under the upper electrode 106.

As described above, by adopting the structure that the plurality of conductive regions 110 are disposed respectively on the storage layer 104, in the middle of the cap layer 105, and under the upper electrode 106, it is possible to shorten an electrical distance from the storage layer 104 to the upper electrode 106, so that it is possible to more effectively reduce a substantial resistance value of the cap layer 105.

Note that, since the method for manufacturing the cap layer 105 according to this example can be easily arrived at from a combination of the manufacturing methods described in the first example to the third example, description thereof is omitted here.

### 1.5.8 Eighth Example

FIG. 18 is a cross-sectional view illustrating the structure example of the cap layer according to the eighth example. As illustrated in FIG. 18, the cap layer 105 according to the eighth example has a structure that is provided with one or more conductive regions 112a that reach the vicinity of the upper electrode 106 from the upper surface of the storage layer 104, and one or more conductive regions 112b that reach the vicinity of the storage layer 104 from the lower surface of the upper electrode 106.

As described above, by extending the conductive regions 112a provided on the upper surface of the storage layer 104 to the vicinity of the upper electrode 106, it is possible to substantially shorten an electrical distance from the storage layer 104 to the upper electrode 106, so that it is possible to more effectively reduce a substantial resistance value of the cap layer 105. Similarly, by extending the conductive regions 112a provided on the lower surface of the upper electrode 106 to the vicinity of the storage layer 104, it is possible to substantially shorten the electrical distance from the storage layer 104 to the upper electrode 106, so that it is possible to more effectively reduce the substantial resistance value of the cap layer 105.

Note that the cap layer 105 having such a structure can be formed by, for example, forming the conductive regions 112a on the storage layer 104, then covering the upper side of the storage layer 104 with the oxide film, forming trenches reaching the vicinity of the storage layer 104 in the oxide film formed thereby, and burying the conductive regions 112b in these trenches.

### 1.6 Function/Effect

As described above, by providing the plurality of conductive regions 110 in the cap layer 105, it is possible to shorten the electrical distance from the storage layer 104 of the lower layer to the upper electrode 106 of the upper layer, so that it is possible to more effectively reduce the substantial resistance value of the cap layer 105. Consequently, even when the film thickness of the cap layer 105 is increased, it is possible to suppress an increase in a Resistance Area (RA), a decrease in a Magnetic Resistance (MR), an increase in a write voltage, and the like, so that it is possible to prevent the device property from lowering.

For example, in the first example where the film thickness of the cap layer 105 is increased by disposing the plurality of conductive regions 110 in the middle of the cap layer 105, it may be possible to achieve the magnetic resistance rate TMR that is high by approximately 50 points while suppressing the increase in the resistance value of the cap layer 105 compared to the case where the film thickness of the cap layer 105 is increased without providing the conductive regions 110. Furthermore, the cap layer 105 has a high perpendicular magnetic anisotropy that is approximately six times compared to a case where the film thickness of the cap layer 105 is increased without providing the conductive regions 110, so that it is possible to embody the MTJ element having a high data retention property.

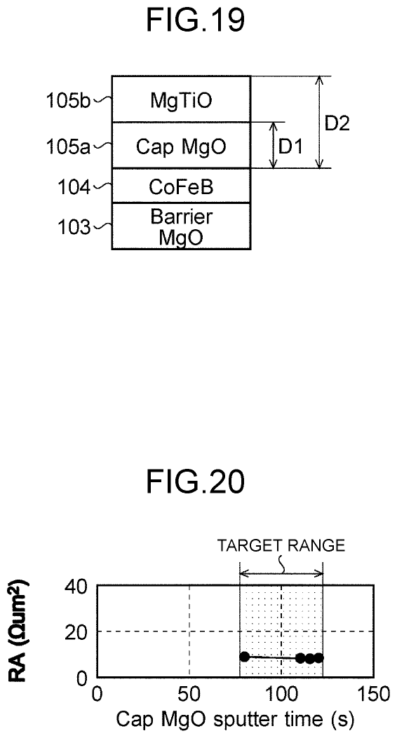

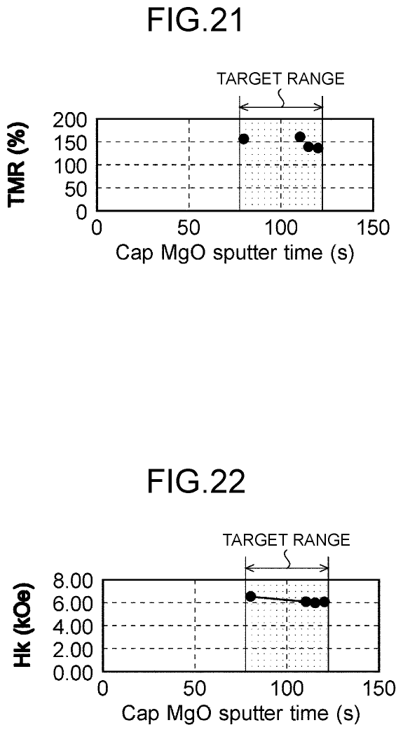

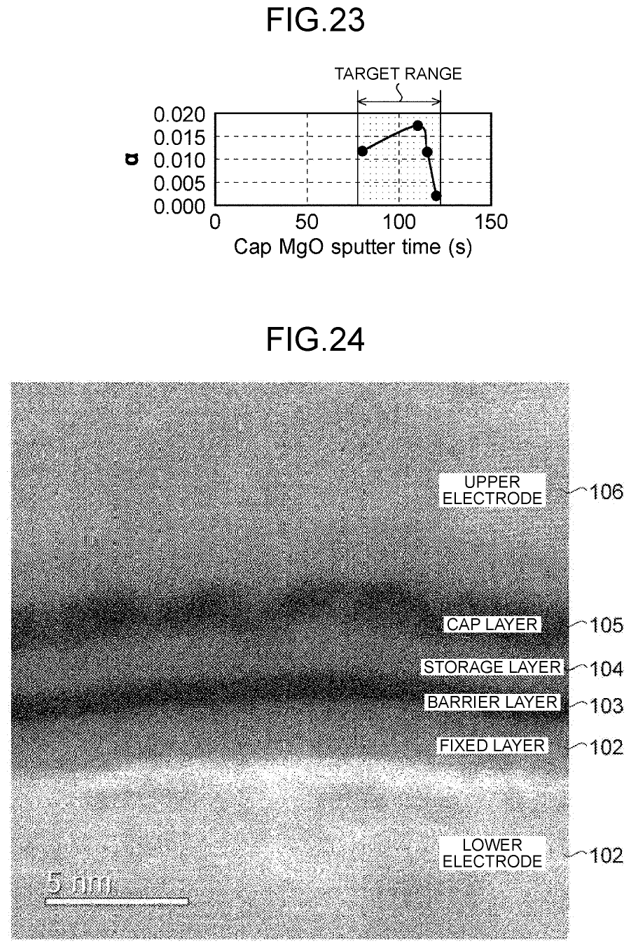

FIG. 19 illustrates a structure (corresponding to the first example) that the cap layer 105 is formed by two layers of a MgO film 105a on the lower layer side and a MgTiO film 105b on the upper layer side, and the plurality of conductive regions 110 are disposed at the interface between the MgO film 105a and the MgTiO film 105b, and FIGS. 20 to 23 illustrate film properties that could be confirmed in cases where the structure illustrated in FIG. 19 was subjected to heat processing at 400° C. for four hours. Note that FIG. 20 illustrates a graph illustrating a change in the resistance area RA with respect to a film formation time of the MgO film 105a. FIG. 21 illustrates a graph illustrating a change in the tunnel magnetoresistance TMR with respect to the film formation time of the MgO film 105a. FIG. 22 illustrates a graph illustrating a change in an anisotropic magnetic field Hk with respect to the film formation time of the MgO film 105a. FIG. 23 illustrates a graph illustrating a change in a damping constant α with respect to the film formation time of the MgO film 105a.

As illustrated in FIGS. 20 to 23, even when the film formation time of the MgO film 105a was increased and the film thickness of the MgO film 105a was increased to improve heat resistance, the resistance area RA did not increase (see FIG. 20), and it was possible to maintain the tunnel magnetoresistance TMR at around 150% (see FIG. 21). Furthermore, it was possible to confirm that the high perpendicular anisotropic magnetic field Hk was maintained at approximately 6 kOe (see FIG. 22), and the damping constant α was reduced by increasing the film thickness of the MgO film 105a (see FIG. 23).

Furthermore, FIG. 24 illustrates a result obtained by actually making the layer structure illustrated in FIG. 19 and observing the layer structure by Scanning Transmission Electron Microscopy (STEM). In FIG. 24, a contrast proportional to the square of the atomic number (Z) can be obtained from a High Angle Annular Dark Field (HAADF) image, a layer appearing black is the oxide layer, and the lower electrode 101/the fixed layer 102/the barrier layer 103/the storage layer 104/the cap layer 105/the upper electrode 106 are formed from the bottom. It has been confirmed by Electron Energy-Loss Spectroscopy (EELS) that a white shadow in the cap layer 105 observed by STEM is metal elements segregated in the oxide.

In view of the above, it is found that the effects exemplified below can be obtained by forming metal segregation in the oxide layer.
It is possible to increase the film thickness of the oxide layer while maintaining the low resistance
It is possible to maintain a high TMR rate and the perpendicular magnetic anisotropy
It is possible to reduce the damping constant

### 2. Second Embodiment

Next, a storage element and a storage device according to the second embodiment of the present disclosure will be described in detail with reference to the drawings. Note that, in the following description, the same components as those of the above-described embodiment will be cited, and redundant description will be omitted.

The above-described first embodiment has assumed that conductive regions 110, 112a, and 112b are the structures grown in the island shape by segregation, and has exemplified the case where the cross-sectional shape of the conductive region 110 is the substantially triangular shape. However, it is not essential that the cross-sectional shape of the conductive region 110 is the substantially triangular shape, and may be variously modified. Hence, the second embodiment will describe a case where the cross-sectional shapes of the conductive regions in the cap layer 105 are trapezoidal shapes will be described.

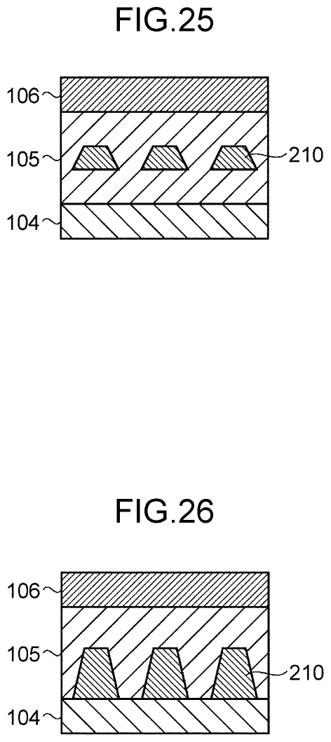

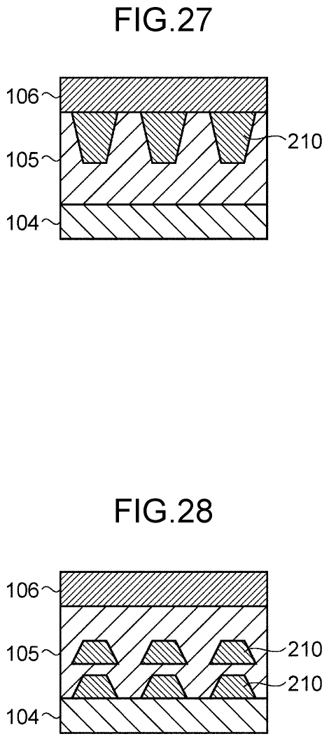

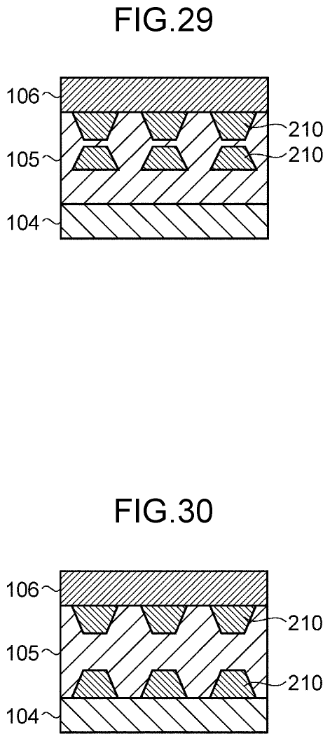

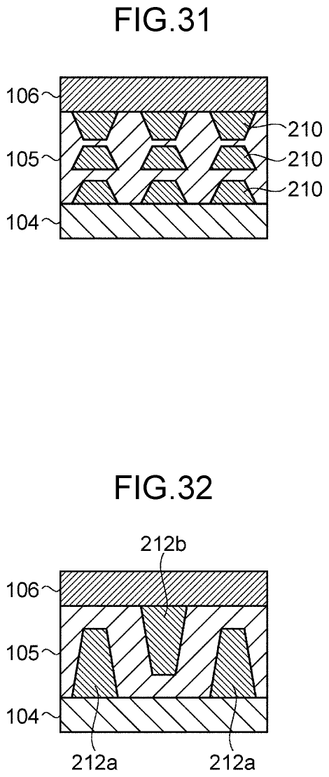

FIGS. 25 to 32 are cross-sectional views illustrating structure examples of the cap layer according to the present embodiment. Note that the first example to the eighth example of the structure of the cap layer illustrated in FIGS. 25 to 32 correspond to the first example to the eighth example of the structure of the cap layer described with reference to FIGS. 11 to 18 in the first embodiment.

As illustrated in FIGS. 25 to 32, the vertical cross-sectional shapes of conductive regions 210, 212a, and 212b according to the present embodiment may be trapezoidal shapes whose bottom surfaces have the diameters expanded compared to the upper surfaces. In this regard, it is assumed that the upper surfaces and the bottom surfaces of the conductive regions 210 and 212b disposed on an upper electrode 106 side are reversed.

Note that, similar to the first embodiment, the horizontal cross-sectional shapes of the individual conductive regions 210, 212a, and 212b may be regular shapes such as circular shapes, elliptical shapes, or polygonal shapes, or may be randomly distorted shapes. Furthermore, the size of each of the conductive regions 210, 212a, and 212b may be, for example, 0.1 to approximately several nm.

The conductive regions 210, 212a, and 212b having such vertical cross-sectional shapes can be formed by, for example, patterning that uses photolithography. However, the conductive regions 210, 212a, and 212b are not limited thereto, and may be formed using a crystal growth process such as island shape growth or column shape growth.

As described above, the vertical cross-sectional shapes of the conductive regions disposed in the cap layer 105 are not limited to the substantially triangular shapes, and may be trapezoidal shapes as exemplified in the present embodiment. Since other configurations, operations, and effects may be the same as those of the above-described embodiment, detailed description thereof is omitted here.

### 3. Third Embodiment

Next, a storage element and a storage device according to the third embodiment of the present disclosure will be described in detail with reference to the drawings. Note that, in the following description, the same components as those of the above-described embodiments will be cited, and redundant description will be omitted.

The vertical cross-sectional shapes of conductive regions 110, 112a, and 112b are the substantially triangular shapes in the above-described first embodiment, and the vertical cross-sectional shapes of conductive regions 210, 212a, and 212b are the trapezoidal shapes in the second embodiment. By contrast with this, the third embodiment exemplifies a case where the vertical cross-sectional shapes of the conductive regions are circular shapes, elliptical shapes, semicircular shapes, or semi-elliptical shapes.

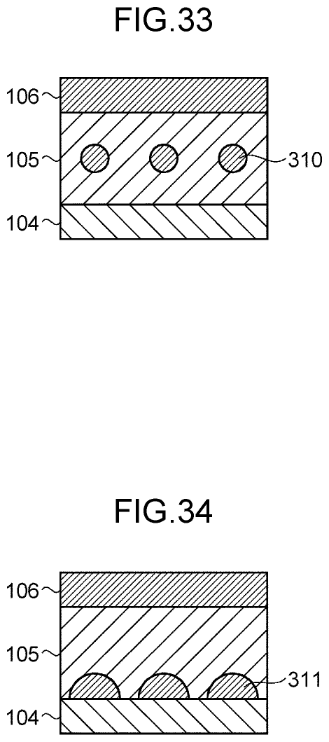

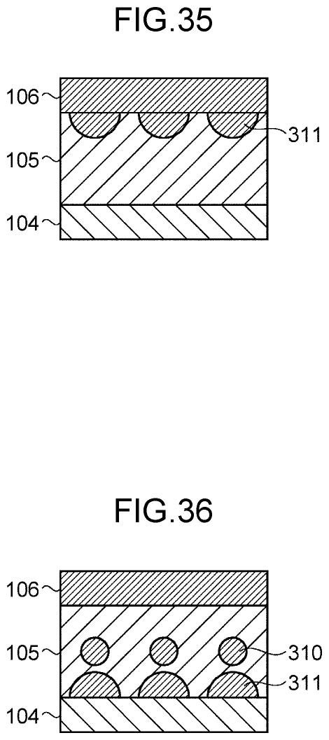

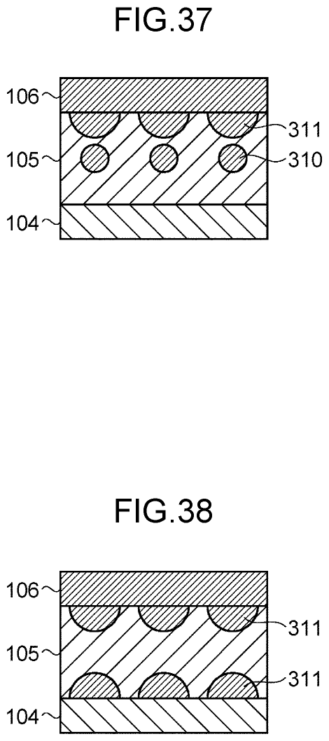

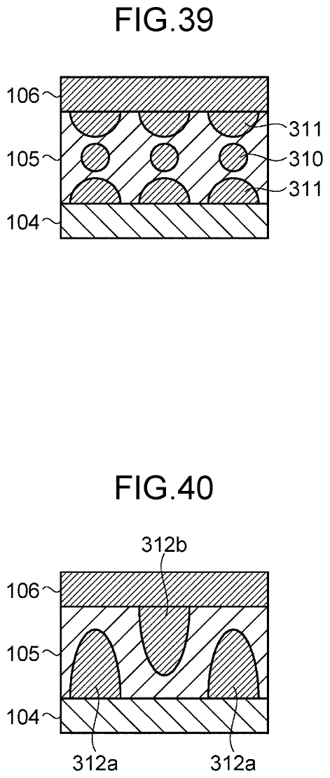

FIGS. 33 to 40 are cross-sectional views illustrating structure examples of a cap layer according to the present embodiment. Note that the first example to the eighth example of the structure of the cap layer illustrated in FIGS. 33 to 40 correspond to the first example to the eighth example of the structure of the cap layer described with reference to FIGS. 11 to 18 in the first embodiment.

As illustrated in FIGS. 33, 36, 37, and 39, the vertical cross-sectional shapes of conductive regions 310 disposed in the middle of the cap layer 105 may be, for example, circular shapes or elliptical shapes. Furthermore, as illustrated in FIGS. 34 to 40, the vertical cross-sectional shapes of conductive regions 311, 312a, and 312b in contact with a storage layer 104 or an upper electrode 106 may be semicircular shapes or semi-elliptical shapes.

Note that, similar to the first embodiment, the horizontal cross-sectional shapes of the individual conductive regions 310, 311, 312a, and 312b may be regular shapes such as circular shapes, elliptical shapes, or polygonal shapes, or may be randomly distorted shapes. Furthermore, the size of each of the conductive regions 310, 311, 312a, and 312b may be, for example, 0.1 to approximately several nm.

The conductive regions 310, 311, 312a, and 312b having such vertical cross-sectional shapes can be formed by, for example, sputtering targeting at metal elements constituting the conductive regions 310, 311, 312a, or 312b, making the metal elements have a granular structure by heat processing in a subsequent process, or a method of processing a metal film formed in a columnar shape by isotropic or anisotropic dry etching or wet etching.

As described above, the vertical cross-sectional shapes of the conductive regions disposed in the cap layer 105 are not limited to substantially triangular shapes or trapezoidal shapes, and may be circular shapes, elliptical shapes, semicircular shapes, or semi-elliptical shapes as exemplified in the present embodiment. Since other configurations, operations, and effects may be the same as those of the above-described embodiments, detailed description thereof is omitted here.

### 4. Fourth Embodiment

Next, a storage element and a storage device according to the fourth embodiment of the present disclosure will be described in detail with reference to the drawings. Note that, in the following description, the same components as those of the above-described embodiments are cited, and redundant description is omitted. In the fourth embodiment, still another example of the vertical cross-sectional shapes of conductive regions will be described citing some examples.

Note that a common matter in the following examples is that, similar to the first embodiment, the horizontal cross-sectional shapes of individual conductive regions 411, 412, 413, 414, 415, 112, 212, and 312 may be regular shapes such as circular shapes, elliptical shapes, or polygonal shapes, or may be randomly distorted shapes. Furthermore, the size of each of the conductive regions 411, 412, 413, 414, 415, 112, 212, and 312 may be, for example, 0.1 to approximately several nm.

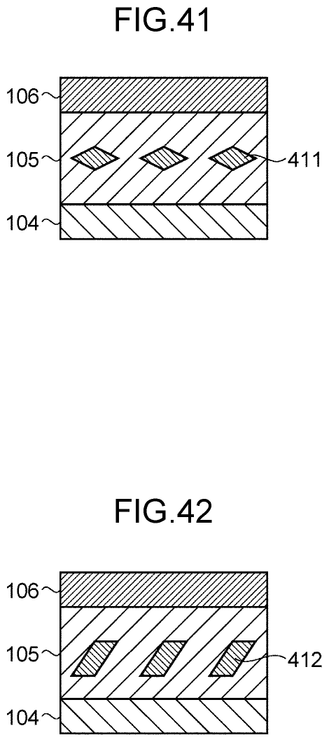

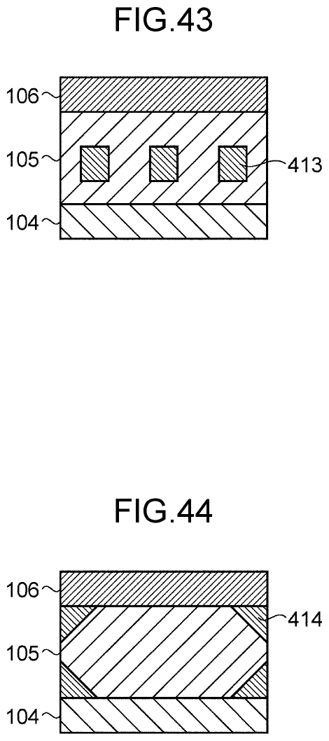

FIGS. 41 to 49 are cross-sectional views illustrating structure examples of a cap layer according to the first example to the ninth example of the present embodiment. The vertical cross-sectional shapes of conductive regions provided in a cap layer 105 may be substantially rhombus shapes like the conductive regions 411 according to the first example illustrated in FIG. 41, may be parallelogram shapes like the conductive regions 412 according to the second example illustrated in FIG. 42, or may be square shapes or rectangular shapes like the conductive regions 413 according to the third example illustrated in FIG. 43.

Furthermore, as in the fourth example illustrated in FIG. 44, the conductive regions 414 may be disposed at four corners in the vertical cross section of the cap layer 105 partitioned as one memory cell 20.

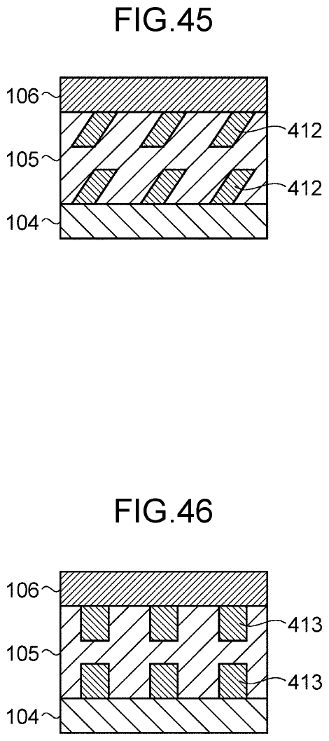

Furthermore, the conductive regions disposed at the interface between the cap layer 105 and a storage layer 104 and/or the interface between the cap layer 105 and an upper electrode 106 may have parallelogram shapes like the conductive regions 412 according to the fifth example illustrated in FIG. 45, or may have square shapes or rectangular shapes like the conductive regions 413 according to the sixth example illustrated in FIG. 46.

Furthermore, as in the seventh example illustrated in FIG. 47, on the interface between the cap layer 105 and the storage layer 104 and/or the interface between the cap layer 105 and the upper electrode 106, conductive regions having different vertical cross-sectional shapes such as the conductive region 112 whose vertical cross-sectional shape is a substantially triangular shape, the conductive region 212 whose vertical cross-sectional shape is a trapezoidal shape, and the conductive region 312 whose vertical cross-sectional shape is a semi-elliptical (or semi-circular) shape may be disposed in a mixed manner. At this time, each conductive region may extend protruding toward the opposing surface side compared to the vertex of the conductive region protruding from the opposing surface. For example, the conductive region 112 may extend toward the storage layer 104 such that the vertex of the conductive region 112 is located closer to the storage layer 104 side than the vertex (or the upper surface) of the conductive region 212 and/or the conductive region 312.

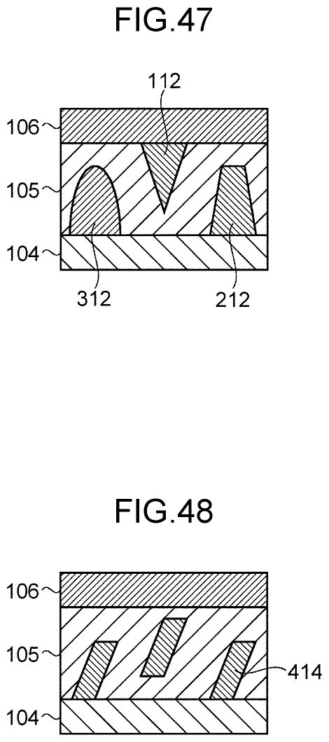

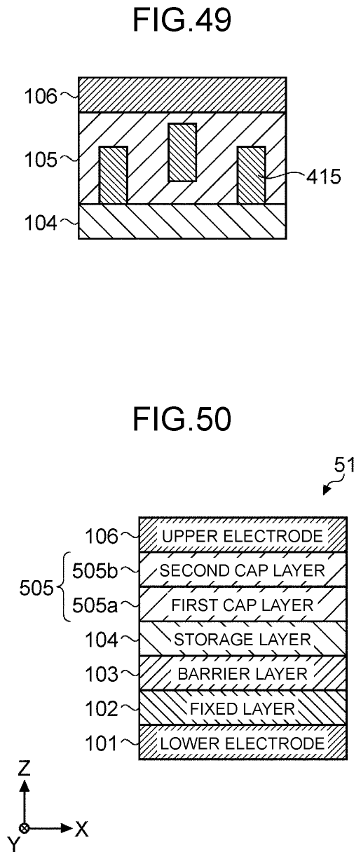

Furthermore, the conductive regions disposed in the middle of the cap layer 105 and at the interface between the cap layer 105 and the storage layer 104 and/or the interface between the cap layer 105 and the upper electrode 106 may have parallelogram shapes like the conductive regions 414 according to the eighth example illustrated in FIG. 48, or may be square shapes or rectangular shapes like the conductive regions 415 according to the ninth example illustrated in FIG. 49. At this time, the lengths in the vertical direction of the conductive regions 414 or the conductive regions 415 may be longer than half of the film thickness of the cap layer 105.

As described above, the vertical cross-sectional shapes of the conductive regions disposed in the cap layer 105 may be variously modified. Since other configurations, operations, and effects may be the same as those of the above-described embodiments, detailed description thereof is omitted here.

### 5. Fifth Embodiment

Next, a storage element and a storage device according to the fourth embodiment of the present disclosure will be described in detail with reference to the drawings. Note that, in the following description, the same components as those of the above-described embodiments will be cited, and redundant description will be omitted.

The above-described embodiments have exemplified the cases where a cap layer 105 has the single layer structure made of the oxide to which the third metal elements are added, or a two layer structure of a layer made of an oxide or an oxide to which the third metal elements are added, and a layer containing a metal. By contrast with this, the present embodiment will describe a case where a cap layer has a laminated structure formed by laminating two or more layers made of an oxide (to which the third metal elements may be added) citing an example.

### 5.1 Schematic Configuration Example of Magnetic Memory Element

FIG. 50 is a cross-sectional view schematically illustrating an example of a schematic configuration of a magnetic memory element according to the present embodiment. A magnetic memory element 51 employs, for example, a configuration where the cap layer 105 is replaced with a cap layer 505 having a laminated structure of a first cap layer 505a and a second cap layer 505b in the same configuration as that of a magnetic memory element 21 described with reference to FIG. 10 in the first embodiment. Note that other components may be the same as those of the magnetic memory element 21 illustrated in FIG. 10, and detailed description thereof is omitted here.

The first cap layer 505a is disposed on the lower layer side of the cap layer 505, that is, the side in contact with a storage layer 104, and the second cap layer 505b is disposed on the upper layer side of the cap layer 505, that is, the side in contact with an upper electrode 106.

Similar to, for example, the cap layer 105 according to the first embodiment, each of the first cap layer 505a and the second cap layer 505b may be, for example, a layer made of, for example, a MOx (M═Si, Mg, Sc, Ti, V, Cr, Ca, Zn, Y, Zr, Mo, Ru, Hf, Ta, W, Re, La, Gd, or Tb) that is an oxide, and a material obtained by adding metal elements (e.g., at least one of Ti, Mo, Al, Co, Fe, V, Cr, Cu, Zn, Nb, Y, Zr, Hf, Au, Pt, Ir, Pd, Ru, Ta, W, Sr, and Ba) to the above oxide. In this case, the conductive regions may be, for example, regions including at least one of, for example, Ti, Mo, Al, Co, Fe, V, Cr, Cu, Zn, Nb, Y, Zr, Hf, Au, Pt, Ir, Pd, Ru, Ta, W, Sr, and Ba, or may be, for example, a laminated film including at least two layers of a layer including at least one of the above oxide and a material obtained by adding third metal elements to the oxide, and a layer including at least one of metals (e.g., Ru, Ta, W, Mo, Ti, Mg, Co, Fe, Al, V, Cr, Cu, Zn, Nb, Y, Zr, Hf, Au, Pt, Ir, and Pd).

At that time, the oxide and/or the metal elements constituting the first cap layer 505a may be the same as or different from the oxide and/or the metal elements constituting the second cap layer 505b.

For example, the first cap layer 505a of the lower layer in contact with the storage layer 104 may be formed using an oxide that can secure the magnetic property of the storage layer 104. Furthermore, by forming the second cap layer 505b of the upper layer in contact with the upper electrode 106 using an oxide having a lower resistance than that of the oxide for forming the first cap layer 505a, it is possible to further reduce the resistance value while increasing the film thickness of the entire cap layer 505.

Note that film thicknesses t1 and t2 of the first cap layer 505a and the second cap layer 505b may be, for example, 5≤t1≤40 [angstroms] and 5≤t2≤40 [angstroms]. In this case, a film thickness t of the entire cap layer 505 may be, for example, 10≤t≤80 [angstroms].

### 5.2 Schematic Structure Example of Cap Layer

Next, structure examples of the cap layer 105 according to the present embodiment will be described below citing some examples.

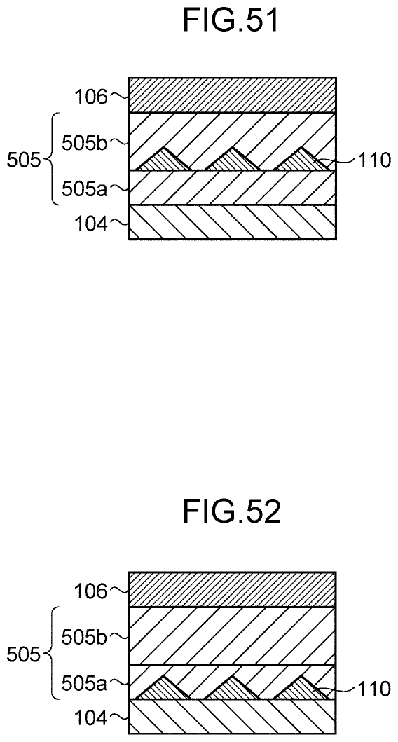

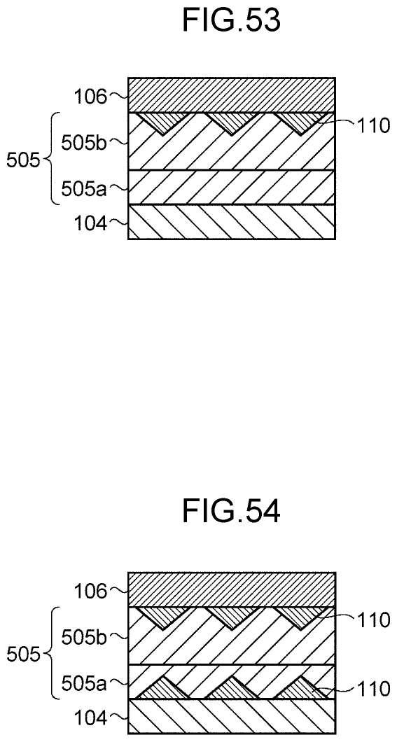

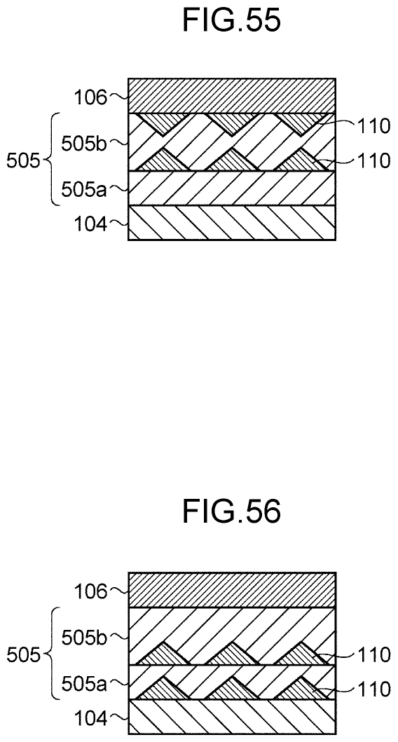

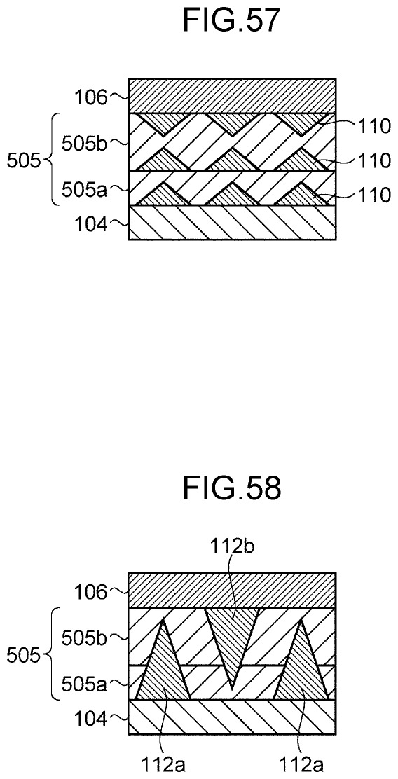

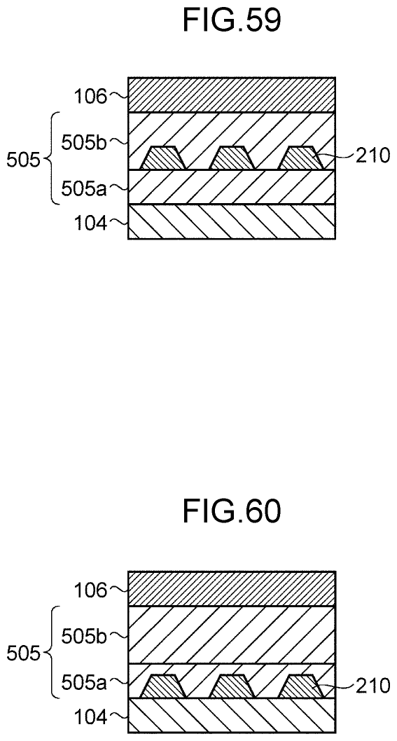

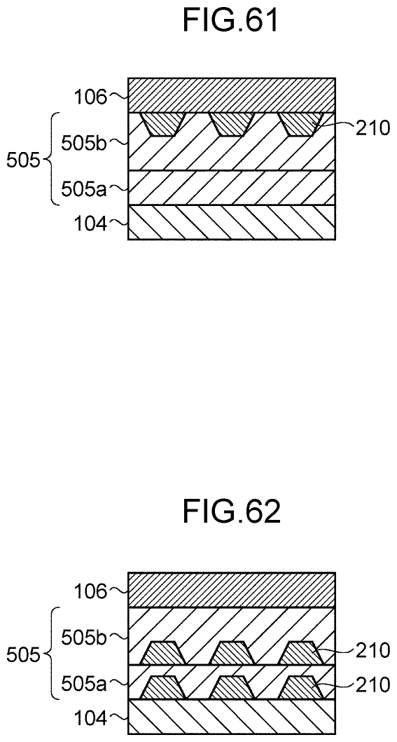

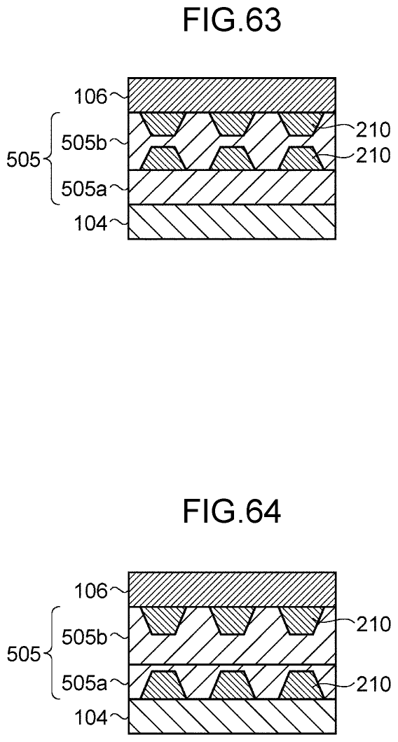

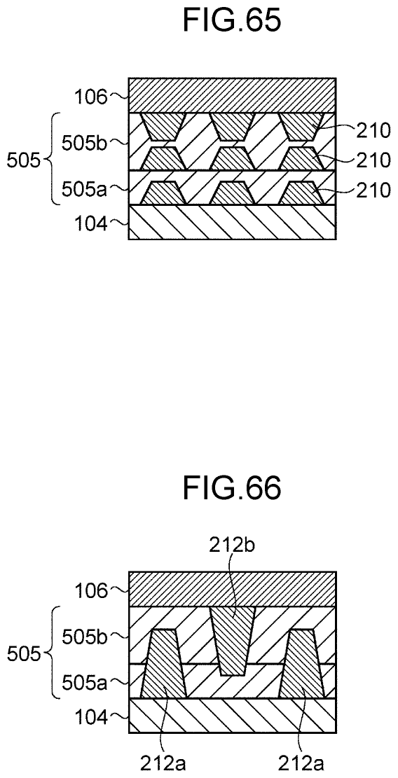

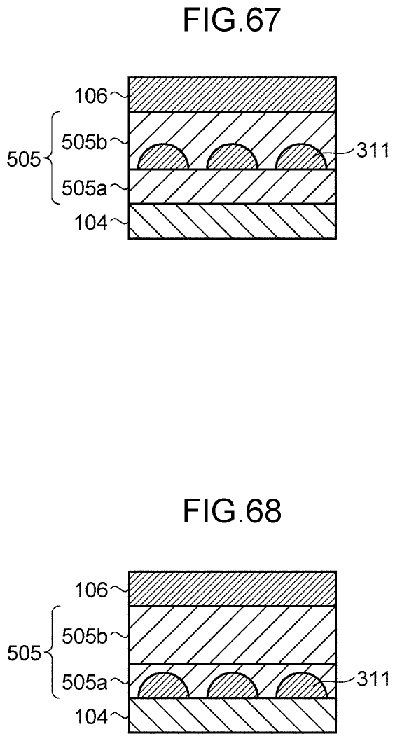

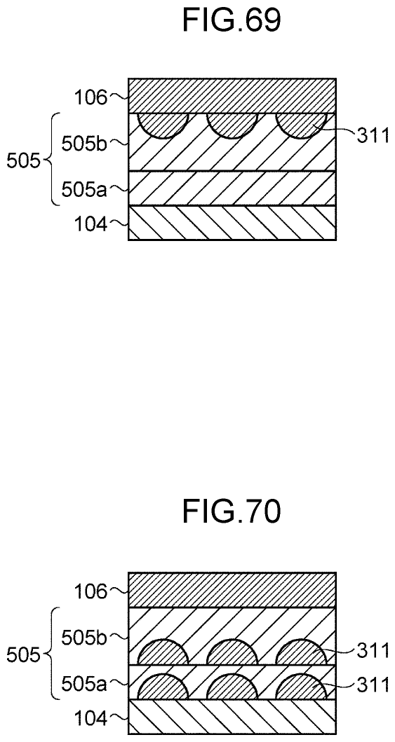

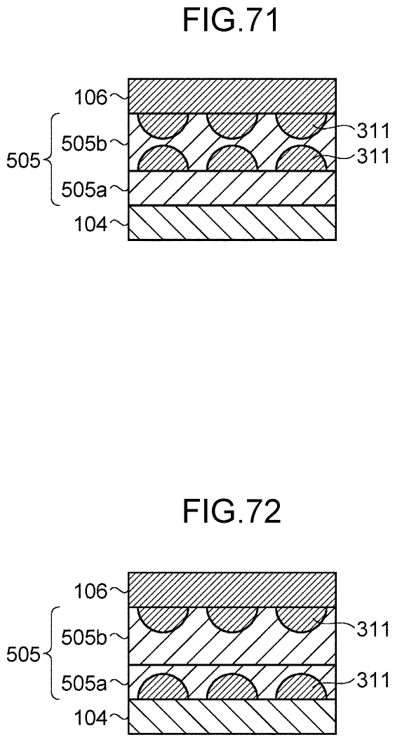

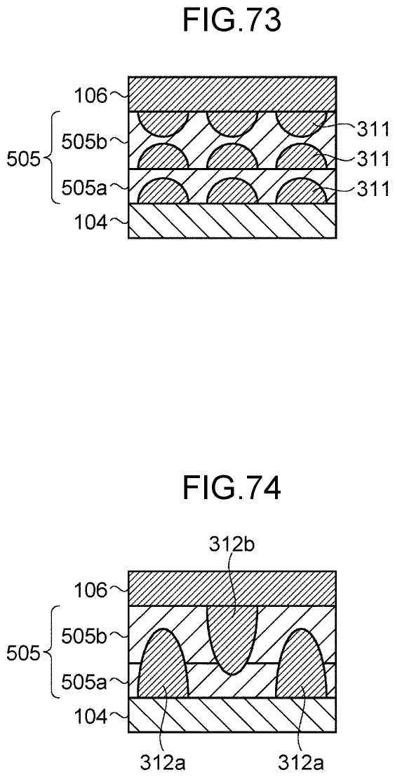

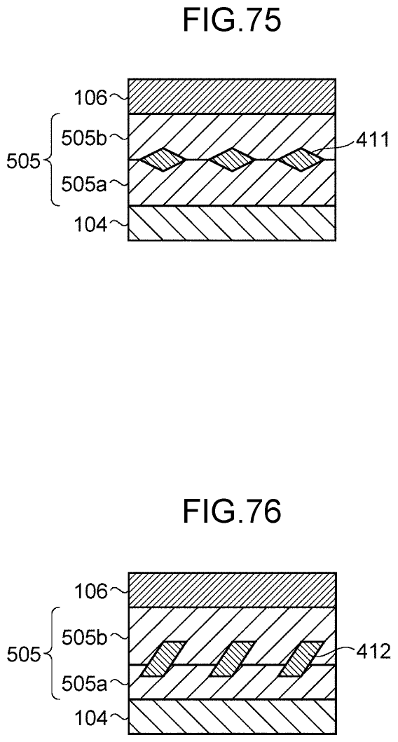

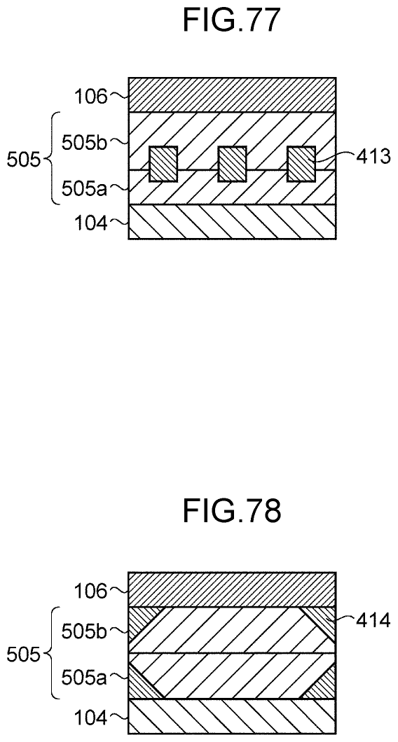

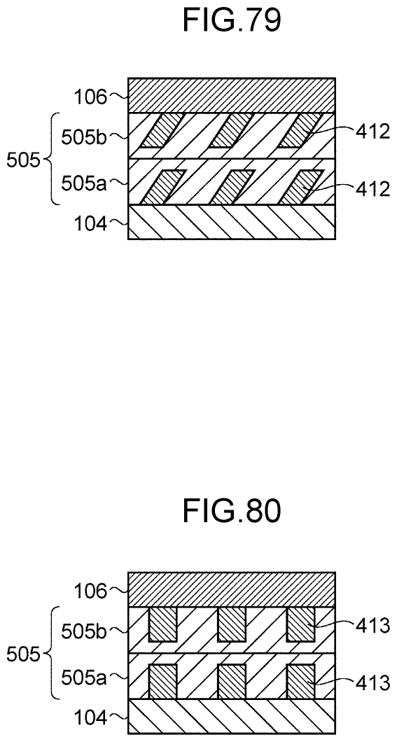

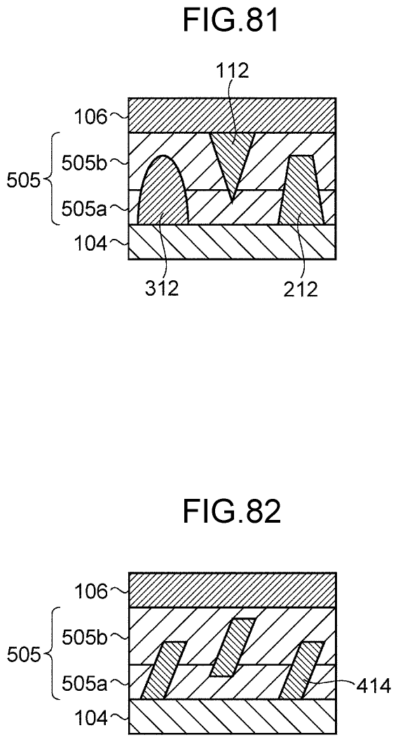

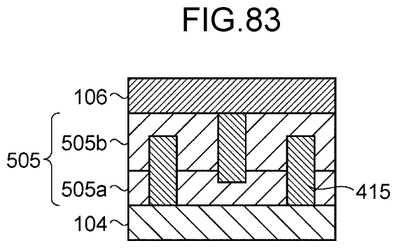

FIGS. 51 to 83 are cross-sectional views illustrating the structure examples of the cap layer according to the present embodiment. Note that the first example to the eighth example of the structure of the cap layer illustrated in FIGS. 51 to 58 correspond to the first example to the eighth example of the structure of the cap layer described with reference to FIGS. 11 to 18 in the first embodiment, the ninth example to the sixteenth example of the structure of the cap layer illustrated in FIGS. 59 to 66 correspond to the first example to the eighth example of the structure of the cap layer described with reference to FIGS. 25 to 32 in the second embodiment, the seventeenth example to the twenty fourth example of the structure of the cap layer illustrated in FIGS. 67 to 74 correspond to the first example to the eighth example of the structure of the cap layer described with reference to FIGS. 33 to 40 in the third embodiment, and the twenty fifth example to the thirty third example of the structure of the cap layer illustrated in FIGS. 75 to 83 correspond to the first example to the ninth example of the structure of the cap layer described with reference to FIGS. 41 to 49 in the fourth embodiment.

In this regard, in the seventeenth example, the twentieth example, the twenty first example, and the twenty fourth example illustrated in FIGS. 67, 70, 71, and 74, the conductive regions disposed in the middle region of the cap layer 505 are replaced with not conductive regions 310 whose vertical cross-sectional shapes are circular shapes or elliptical shapes, but conductive regions 311 whose vertical cross-sectional shapes are semicircular shapes or semi-elliptical shapes.

Furthermore, conductive regions 110, 210, and 311 disposed in the middle of the cap layer 505 may be disposed on the upper surface of the first cap layer 505a, or may be disposed in the middle of the first cap layer 505a or the second cap layer 505b.

As described above, the oxide film constituting the cap layer has two or more layers, so that, as described above, by, for example, using for the first cap layer 505a of the lower layer in contact with the storage layer 104 the oxide that can secure the magnetic property of the storage layer 104, and using for the second cap layer 505b of the upper layer in contact with the upper electrode 106 the oxide having a lower resistance than that of the first cap layer 505a, it is possible to further reduce the resistance value while increasing the film thickness of the entire cap layer 505, and, consequently, it is possible to further improve the device property of the magnetic memory element 51.

Since other configurations, operations, and effects may be the same as those of the above-described embodiments, detailed description thereof is omitted here.

Although the embodiments of the present disclosure have been described above, the technical scope of the present disclosure is not limited to the above-described embodiments as is, and various modifications can be made without departing from the gist of the present disclosure. Furthermore, components according to different embodiments and modifications may be appropriately combined.

Furthermore, the effects according to each embodiment described in the description are merely examples and are not limited thereto, and other effects may be provided.

Note that the technique according to the present disclosure can also employ the following configurations.

(1)

A storage element comprising:
a fixed layer that has a fixed magnetization direction;
an insulation layer that is disposed on the fixed layer;
a storage layer that is disposed on the insulation layer and changes a magnetization direction according to an applied current; and
a cap layer that is disposed on the storage layer and made of an oxide,
wherein the cap layer includes a plurality of conductive regions having higher conductivity than conductivity of the oxide.
   (2)

The storage element according to (1), wherein the plurality of conductive regions include at least one of Ru, Ta, W, Mo, Ti, Mg, Co, Al, V, Cr, Cu, Zn, Nb, Y, Zr, Hf, Au, Pt, Ir, Pd, and Fe.

(3)

The storage element according to (1) or (2), wherein the plurality of conductive regions include a conductive material having low wettability with respect to the storage layer or the oxide.

(4)

The storage element according to any one of (1) to (3), wherein each of the conductive regions is a structure that is grown in an island shape by segregation.

(5)

The storage element according to any one of (1) to (4), wherein each of the conductive regions is a structure that has a granular structure.

(6)

The storage element according to any one of (1) to (5), wherein a coverage of the plurality of conductive regions with respect to a surface parallel to an upper surface or a bottom surface of the cap layer is 1% or more and 99% or less.

(7)

The storage element according to any one of (1) to (6), wherein a vertical cross-sectional shape of at least one of the plurality of conductive regions is one of a substantially triangular shape, a trapezoidal shape, a circular shape, an elliptical shape, a semicircular shape, a semi-elliptical shape, a rhombus shape, a parallelogram shape, a square shape, and a rectangular shape.

(8)

The storage element according to any one of (1) to (7), wherein at least part of the plurality of conductive regions is disposed in a vicinity of a middle between an upper surface and a bottom surface of the cap layer.

(9)

The storage element according to any one of (1) to (8), wherein at least part of the plurality of conductive regions is disposed on a bottom surface of the cap layer.

(10)

The storage element according to any one of (1) to (9), wherein at least part of the plurality of conductive regions is disposed on an upper surface of the cap layer.

(11)

The storage element according to any one of (1) to (10), wherein a length of at least one of the plurality of conductive regions in a direction vertical to an upper surface or a bottom surface of the cap layer is half or more of a film thickness of the cap layer.

(12)

The storage element according to any one of (1) to (11), wherein the oxide is at least one oxide of Si, Mg, Sc, Ti, V, Cr, Ca, Zn, Y, Zr, Mo, Ru, Hf, Ta, W, Re, La, Gd, and Tb.

(13)

The storage element according to any one of (1) to (12), wherein the cap layer is a layer formed by adding at least one of Ti, Mo, Al, Co, Fe, V, Cr, Cu, Zn, Nb, Y, Zr, Hf, Au, Pt, Ir, Pd, Ru, Ta, W, Sr, and Ba to the oxide.

(14)

The storage element according to any one of (1) to (13), wherein the cap layer has a laminated structure of a layer of the oxide and at least one layer of Ti, Mo, Al, Co, Fe, V, Cr, Cu, Zn, Nb, Y, Zr, Hf, Au, Pt, Ir, Pd, Ru, Ta, W, Sr, and Ba.

(15)

The storage element according to any one of (1) to (14), wherein a film thickness of the cap layer is 10 angstroms or more and 40 angstroms or less.

(16)

The storage element according to any one of (1) to (14), wherein the cap layer has a laminated structure of a first layer containing a first oxide, and a second layer containing a second oxide different from the first oxide and disposed on the first layer.

(17)

The storage element according to (16), wherein the first oxide is an oxide that secures a magnetic property of the storage layer.

(18)

The storage element according to (16) or (17), wherein the second oxide is an oxide that has a lower resistance than a resistance of the first oxide.

(19)

The storage element according to any one of (16) to (18), wherein
a film thickness of the first layer is five angstroms or more and 40 angstroms or less,
a film thickness of the second layer is five angstroms or more and 40 angstroms or less, and
a film thickness of the cap layer is 10 angstroms or more and 80 angstroms or less.
   (20)

A storage device comprising:
a plurality of storage elements that are aligned in a matrix pattern; and
a wiring that is connected to the plurality of storage elements, wherein
each of the storage elements includes:
a fixed layer that has a fixed magnetization direction;
an insulation layer that is disposed on the fixed layer;
a storage layer that is disposed on the insulation layer and changes a magnetization direction according to an applied current; and
a cap layer that is disposed on the storage layer and made of an oxide, and
the cap layer includes a plurality of conductive regions having higher conductivity than conductivity of the oxide.

### REFERENCE SIGNS LIST

1 MEMORY MACRO
11 MEMORY CELL ARRAY
12a, 12b SELECTION CIRCUIT
13 DETECTION CIRCUIT
20 MEMORY CELL
21, 51 MAGNETIC MEMORY ELEMENT
22 SELECTION TRANSISTOR
23 SOURCE REGION
24 DRAIN REGION
25 ELEMENT ISOLATION REGION
26 SEMICONDUCTOR SUBSTRATE
100 STORAGE DEVICE
101 LOWER ELECTRODE
102 FIXED LAYER
103 BARRIER LAYER
104 STORAGE LAYER
105, 505 CAP LAYER
106 UPPER ELECTRODE
110, 112a, 112b, 210, 212a, 212b, 310, 311, 312a, 312b,
411, 412, 413, 414, 415 CONDUCTIVE REGION
505a FIRST CAP LAYER
505b SECOND CAP LAYER
BL BIT LINE
SI SENSE LINE
WL WORD LINE

1. A storage element comprising:
a fixed layer that has a fixed magnetization direction;
an insulation layer that is disposed on the fixed layer;
a storage layer that is disposed on the insulation layer and changes a magnetization direction according to an applied current; and
a cap layer that is disposed on the storage layer and made of an oxide,
wherein the cap layer includes a plurality of conductive regions having higher conductivity than conductivity of the oxide.

2. The storage element according to claim 1, wherein the plurality of conductive regions include at least one of Ru, Ta, W, Mo, Ti, Mg, Co, Al, V, Cr, Cu, Zn, Nb, Y, Zr, Hf, Au, Pt, Ir, Pd, and Fe.

3. The storage element according to claim 1, wherein the plurality of conductive regions include a conductive material having low wettability with respect to the storage layer or the oxide.

4. The storage element according to claim 1, wherein each of the conductive regions is a structure that is grown in an island shape by segregation.

5. The storage element according to claim 1, wherein each of the conductive regions is a structure that has a granular structure.

6. The storage element according to claim 1, wherein a coverage of the plurality of conductive regions with respect to a surface parallel to an upper surface or a bottom surface of the cap layer is 1% or more and 99% or less.

7. The storage element according to claim 1, wherein a vertical cross-sectional shape of at least one of the plurality of conductive regions is one of a substantially triangular shape, a trapezoidal shape, a circular shape, an elliptical shape, a semicircular shape, a semi-elliptical shape, a rhombus shape, a parallelogram shape, a square shape, and a rectangular shape.

8. The storage element according to claim 1, wherein at least part of the plurality of conductive regions is disposed in a vicinity of a middle between an upper surface and a bottom surface of the cap layer.

9. The storage element according to claim 1, wherein at least part of the plurality of conductive regions is disposed on a bottom surface of the cap layer.

10. The storage element according to claim 1, wherein at least part of the plurality of conductive regions is disposed on an upper surface of the cap layer.

11. The storage element according to claim 1, wherein a length of at least one of the plurality of conductive regions in a direction vertical to an upper surface or a bottom surface of the cap layer is half or more of a film thickness of the cap layer.

12. The storage element according to claim 1, wherein the oxide is at least one oxide of Si, Mg, Sc, Ti, V, Cr, Ca, Zn, Y, Zr, Mo, Ru, Hf, Ta, W, Re, La, Gd, and Tb.

13. The storage element according to claim 1, wherein the cap layer is a layer formed by adding at least one of Ti, Mo, Al, Co, Fe, V, Cr, Cu, Zn, Nb, Y, Zr, Hf, Au, Pt, Ir, Pd, Ru, Ta, W, Sr, and Ba to the oxide.

14. The storage element according to claim 1, wherein the cap layer has a laminated structure of a layer of the oxide and at least one layer of Ti, Mo, Al, Co, Fe, V, Cr, Cu, Zn, Nb, Y, Zr, Hf, Au, Pt, Ir, Pd, Ru, Ta, W, Sr, and Ba.

15. The storage element according to claim 1, wherein a film thickness of the cap layer is 10 angstroms or more and 40 angstroms or less.

16. The storage element according to claim 1, wherein the cap layer has a laminated structure of a first layer containing a first oxide, and a second layer containing a second oxide different from the first oxide and disposed on the first layer.

17. The storage element according to claim 16, wherein the first oxide is an oxide that secures a magnetic property of the storage layer.

18. The storage element according to claim 16, wherein the second oxide is an oxide that has a lower resistance than a resistance of the first oxide.

19. The storage element according to claim 16, wherein a film thickness of the first layer is five angstroms or more and 40 angstroms or less,
a film thickness of the second layer is five angstroms or more and 40 angstroms or less, and
a film thickness of the cap layer is 10 angstroms or more and 80 angstroms or less.

20. A storage device comprising:
a plurality of storage elements that are aligned in a matrix pattern; and
a wiring that is connected to the plurality of storage elements, wherein
each of the storage elements includes:
a fixed layer that has a fixed magnetization direction;
an insulation layer that is disposed on the fixed layer;
a storage layer that is disposed on the insulation layer and changes a magnetization direction according to an applied current; and
a cap layer that is disposed on the storage layer and made of an oxide, and
the cap layer includes a plurality of conductive regions having higher conductivity than conductivity of the oxide.
